(19) United States
(12) Patent Application Publication
(10) Pub. No.: US 2026/0247530 A1
(43) Pub. Date: Aug. 20, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Se Woong NA, Seoul (KR); Kee Han LEE, Seoul (KR); Jin Ho SONG, Seoul (KR)

(73) Assignee: LG INNOTEK CO., LTD., Seoul (KR)

(21) Appl. No.: 19/162,630

(22) PCT Filed: Mar. 7, 2024
(86) PCT No.: PCT/KR2024/002972

§ 371 Date: Sep. 5, 2025

(30) Foreign Application Priority Data
Mar. 7, 2023 (KR) 10-2023-0029995

(51) Int. Cl. H05K 1/11; H05K 1/181; H05K 3/40; H10W 90/10

(52) U.S. Cl. CPC H05K 1/113; H05K 1/181; H05K 3/4007; H05K 2201/0266; H05K 2201/09036; H05K 2201/09472; H10W 90/10

(57) ABSTRACT

A semiconductor package according to an embodiments an insulating layer; a protective layer disposed on the insulating layer; an electrode part embedded in the insulating layer; and a bump part disposed on the protective layer, wherein the electrode part includes a via electrode connected to the bump part; each of the insulating layer and the protective layer includes a through hole in which the via electrode is disposed, and an inner wall of the insulating layer and an inner wall of the protective layer forming the through hole are positioned on a same plane.

### TECHNICAL FIELD

An embodiment relates to a circuit board and a semiconductor package including the same.

### BACKGROUND ART

As performances of electric/electronic products progresses, technologies for disposing a greater number of semiconductor devices on a semiconductor package substrate of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

In addition, semiconductor packages applied to products that provide the Internet of Things (IoT), autonomous vehicles, and high-performance servers are expanding a concept to semiconductor chiplets as the number of semiconductor devices and/or the size of each semiconductor device increases in line with the trend toward high integration, or as the functional parts of semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

Meanwhile, a package substrate and/or interposer applied to a semiconductor package may be equipped with a connection member connected to a semiconductor device and/or a semiconductor chiplet. The connection member functions to horizontally connect a plurality of semiconductor devices and/or semiconductor chiplets. Accordingly, the connection member may be embedded in the package substrate and/or the interposer. At this time, the package substrate and/or the interposer may be equipped with a plurality of bump parts connected to the semiconductor device and/or the semiconductor chiplet. The bump parts may include a first bump part that does not overlap with the connection member in a vertical direction, and a second bump part that overlaps with the connection member in the vertical direction and overlaps with the first bump part in a horizontal direction.

At this time, the number of pads of the connection member and the number of terminals on the semiconductor device are increasing. Accordingly, a fine pitch is required between two adjacent bumps among the first bump parts connected to the pads of the connection member and the terminals of the semiconductor device. However, according to conventional technology, a pitch between two adjacent bumps exceeds at least 60 μm. That is, the circuit board includes an electrode part penetrating an insulating layer and connected to a pad of a connection member, and a bump part penetrating a protective layer and disposed between a terminal of a semiconductor device and the electrode part. At this time, the electrode part includes a via electrode penetrating the insulating layer and a pad electrode disposed on the via electrode. In addition, the bump part includes a through part penetrating the protective layer and a protruding part disposed on the through part. At this time, a pitch between two adjacent bumps is determined by a width/spacing of the via electrode, a width/spacing of the pad electrode, a width/spacing of the through part, and a width/spacing of the protruding part. At this time, according to a prior art, there is a limit to reducing the width of the via electrode and the through part, and as a result, the pitch between two adjacent bumps exceeds 60 μm. Accordingly, there is a limit to improving the circuit integration of the semiconductor package and miniaturizing the semiconductor package.

### DISCLOSURE

### Technical Problem

The embodiment provides a semiconductor package having a novel structure.

In addition, the embodiment provides a semiconductor package capable of minimizing a pitch between a plurality of bumps.

In addition, the embodiment provides a semiconductor package capable of controlling a height deviation between multiple bump parts connected to a semiconductor device.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment comprises an insulating layer; a protective layer disposed on the insulating layer; an electrode part embedded in the insulating layer; and a bump part disposed on the protective layer, wherein the electrode part includes a via electrode connected to the bump part; each of the insulating layer and the protective layer includes a through hole in which the via electrode is disposed, and an inner wall of the insulating layer and an inner wall of the protective layer forming the through hole are positioned on a same plane.

In addition, a width of an upper surface of the via electrode satisfies a range of 90% to 110% of a width of a lower surface of the via electrode.

In addition, the width of the upper surface of the via electrode is same as the width of the lower surface of the via electrode.

In addition, the through hole of the protective layer includes a first part in contact with a side surface of the via electrode and including an inner wall having a first slope, and a second part provided on the first part and having a second slope different from the first slope.

In addition, the inner wall of the first part is same as a slope of the side surface of the via electrode.

In addition, the slope of the side surface of the via electrode satisfies a range of 85 degrees to 95 degrees with respect to the upper surface of the via electrode.

In addition, an inner wall of the second part includes a curved surface, and wherein a lower surface of the bump part includes a portion in contact with the curved surface.

In addition, the semiconductor package further comprises a metal layer disposed between the bump part and the via electrode, wherein the metal layer includes a different metal material from at least one of the bump part and the via electrode.

In addition, the bump part is provided in the second part of the through hole of the protective layer, and a width of the bump part is less than or equal to a width of the second part.

In addition, the insulating layer includes a first filler, and wherein an interface between an upper surface of the insulating layer and a lower surface of the protective layer includes at least one of a convex surface and a concave surface corresponding to a curvature of the first filler.

In addition, the protective layer includes a second filler, and the via electrode overlaps the first and second fillers in a horizontal direction and does not contact the first and second fillers.

In addition, the semiconductor package further comprises a connection member embedded in the insulating layer, and the bump part is provided in plurality so as to overlap the connection member in a vertical direction, and a horizontal distance between centers of two adjacent bump parts among the plurality of bump parts is 40 μm or less.

Meanwhile, a semiconductor package according to an embodiment includes an insulating layer; a protective layer disposed on the insulating layer; and a bump part penetrating from an upper surface of the protective layer to a partial region of the insulating layer, wherein the bump part includes a through part penetrating from an upper surface of the protective layer to a partial region of the insulating layer, and a protruding part disposed on the through part and protruding on the protective layer.

In addition, the through part includes: a first through part penetrating the insulating layer; and a second through part penetrating the protective layer, wherein a side surface of the first through part does not have a step, a side surface of the second through part does not have a step, and a width of the second through part is greater than a width of the first through part.

In addition a slope of the side surface of the first through part is the same as a slope of the side surface of the second through part.

In addition, the protective layer includes a first portion disposed on the insulating layer, and a second portion extending from the first portion and penetrating the insulating layer, wherein the second portion surrounds a side portion of the through part of the bump part.

In addition, a width of the upper surface of the through part satisfies a range of 90% to 110% of a width of the lower surface of the through part, and a side surface of the through part does not have a step.

In addition, the insulating layer includes a first filler, and an interface between an upper surface of the insulating layer and a lower surface of the protective layer includes a first convex surface and a first concave surface corresponding to a curvature of the first filler.

In addition, the protective layer includes a second filler, and an upper surface of the protective layer includes a second convex surface and a second concave surface corresponding to a curvature of the second filler.

In addition, the semiconductor package further includes a connection member embedded in the insulating layer, and a plurality of bump parts are provided so as to overlap with the connection member in a vertical direction, and a horizontal distance between centers of two adjacent bump parts among the plurality of bump parts is 40 μm or less.

### Advantageous Effects

The embodiment includes a protective layer and a bump part penetrating from the upper surface of the protective layer to a partial region of the protective layer. At this time, the protective layer includes a through hole corresponding to the bump part. The through hole in the protective layer is formed using a dry film pattern. Accordingly, the embodiment can refine the width and pitch of the through hole provided in the protective layer. For example, the embodiment can allow a horizontal distance between centers of at least two adjacent through holes to be 40 μm or less. Accordingly, the embodiment can allow a horizontal distance between centers of adjacent bump parts to be 40 μm or less.

Therefore, the embodiment can minimize a pitch of the bump part to 40 μm or less, thereby improving circuit integration and miniaturizing the circuit board and semiconductor package. In addition, the embodiment can reduce a distance between a plurality of bump parts, thereby minimizing a transmission distance of signals transmitted through the corresponding bump parts. Therefore, the embodiment may minimize signal transmission loss that increases according to the transmission distance of the signal, thereby improving communication characteristics of a circuit board and a semiconductor package. In addition, the embodiment can allow a semiconductor device disposed on a circuit board to operate stably, thereby allowing an electronic product such as a server to which a semiconductor package is applied to operate stably.

In addition, the embodiment includes a via electrode. The via electrode is formed by penetrating an insulating layer disposed under a protective layer. At this time, the via electrode protrudes on the insulating layer. In addition, the via electrode penetrates at least a portion of the protective layer. Thus, the embodiment can eliminate via land portions (e.g., annual rings) that are formed on the via electrode and have a width greater than a width of the via electrode. Therefore, the embodiment can minimize the width and pitch of the via electrode, thereby further minimizing the width and pitch of the bump parts disposed on the via electrode.

Furthermore, the embodiment can minimize a height deviation of a plurality of bump parts. That is, the embodiment includes a first bump part overlapping a connection member in a vertical direction and a second bump part that does not overlap the connection member in a vertical direction. At this time, the first bump part and the second bump part can be manufactured in a same manner and can have a same size. Therefore, the embodiment can minimize a height deviation caused by a size difference between the first and second bump parts. Through this, the embodiment can allow a semiconductor device to be stably disposed on the first bump part and the second bump part. Therefore, the embodiment can improve operating characteristics of the first and second semiconductor devices. In addition, the embodiment can allow the first and second semiconductor devices to operate smoothly, thereby allowing the electronic product or server to operate smoothly.

In addition, the embodiment allows the first and second bump parts to have the same height, thereby resolving issues such as impedance changes and signal transmission loss caused by variations in the thickness of the first and second bump parts, as well as issues with semiconductor devices being disposed in an inclined position, thereby further improving electrical reliability.

In addition, the embodiment may allow each of the via electrode and the bump part to be disposed in a through hole provided in the insulating layer and the protective layer without contacting the filler. This is because the through holes formed in the insulating layer and protective layer are formed using a dry film rather than a laser process. Through this, the embodiment can reduce a surface roughness of the via electrode and the bump part, thereby minimizing the signal transmission loss that increases in proportion to the surface roughness. Accordingly, the embodiment can further improve the operating characteristics of the semiconductor device.

Thus, the embodiment may allow the side surfaces of the bump part to be substantially vertical. Furthermore, the embodiment may allow an inner wall of a through hole provided in the protective layer and overlapping the bump part in a vertical direction to be vertical. Through this, the embodiment can solve a problem that occurs when a through hole is formed in a protective layer using a laser process in a prior art. That is, in the prior art, a through hole is formed in the protective layer using a laser process, and thus the through hole of the protective layer has a curved portion whose width is rapidly narrowed along the vertical direction. In addition, stress may be applied to the curved portion due to a heat cycle of the protective layer caused by heat generated during the operation of the semiconductor device or a subsequent process, which may cause a crack to occur at an interface between the bump part and the electrode part, or a reliability problem may occur in which the bump part is peeled off from the electrode part. To solve this, when a width of the bump part is increased, it may be difficult to adjust a pitch between a plurality of bonding parts to 40 μm or less, and accordingly, an area of the semiconductor package may increase and thus it may be difficult to reduce the thickness. Furthermore, when a through hole is formed in the protective layer using a laser process, a process time may increase, which may reduce productivity. Furthermore, when a through hole having a relatively small width is formed through a laser process, it may be difficult to align the laser beams at a correct position, and accordingly, defects such as misalignment of the through hole may occur, thereby deteriorating product yield. On the contrary, in the embodiment, a through hole may be formed in the protective layer using a dry film, and a curved part may be removed. Furthermore, the embodiment may further reduce the pitch between a plurality of bump parts, and prevent cracks that may occur when the semiconductor device is mounted on the bump part having a fine pitch.

Meanwhile, an upper surface of the insulating layer and/or protective layer of the embodiment includes a convex surface and a concave surface formed by a process for thinning the thickness. The convex surface and the concave surface can increase a surface area of the insulating layer and/or the protective layer. In this case, the convex surface and the concave surface can function to mitigate the degree of expansion of the insulating layer and/or the protective layer due to heat generated during the operation of the semiconductor device. For example, since the convex surface and the concave surface have different thicknesses and/or heights, the volume deformed during thermal expansion may differ. That is, the concave surface may have a lower height than the convex surface, and due to the difference in thermal expansion rates between the convex surface and the concave surface, thermal deformation of the semiconductor package can be suppressed as a whole. Therefore, the embodiment can prevent electrical disconnection of a semiconductor device coupled to an upper portion of the semiconductor package during thermal expansion, thereby improving product reliability.

Furthermore, the embodiment can form via electrodes and/or bump parts that vertically overlap with the connection member and via electrodes and/or bump parts that do not vertically overlap with the connection member using the same method, while ensuring that the via electrodes and/or bump parts that overlap with the connection member in a vertical direction have a required width and pitch. This can improve product yield.

Furthermore, the bump parts of the embodiment penetrate from the upper surface of the protective layer to a partial region of the insulating layer. For example, the embodiment forms a through hole in each of the insulating layer and the protective layer. Thereafter, the embodiment simultaneously fills the through hole in the insulating layer and the through hole in the protective layer with a conductive material. Through this, the bump part can penetrate the insulating layer while penetrating the protective layer. Through this, the embodiment can simplify the manufacturing process and further improve product yield.

In addition, a side surface of the bump part may have a step. For example, the bump part may include a first through part penetrating the insulating layer, a second through part penetrating the protective layer, and a protruding part disposed on the second through part. In this case, side surfaces of the first through part, the second through part, and the protruding part may have a step. Through this, the embodiment can efficiently distribute the stress acting on the first through part, the second through part, and the protruding part. For example, stress acting due to thermal expansion and/or thermal contraction may not be concentrated in a specific region of the bump part due to the step, and may be evenly dispersed in an entire region of the bump part. Accordingly, the embodiment can solve the reliability problem of cracks occurring in the bump part due to stress acting due to thermal expansion and/or thermal contraction. Furthermore, the embodiment can increase a contact area between the bump part and the insulating layer and/or the protective layer by allowing the side surface of the bump part to have a step, thereby improving the bonding strength. Accordingly, the embodiment can solve the problem of the bump part being peeled off from the insulating layer and/or the protective layer, thereby allowing the semiconductor package to operate stably.

Furthermore, the protective layer of the embodiment penetrates at least a portion of the insulating layer. For example, the protective layer includes a first portion formed on the insulating layer and a second portion formed in a through hole of the insulating layer. The second portion of the protective layer surrounds a side portion of the through part of the bump part formed in the through hole of the insulating layer. Accordingly, the through part of the bump part can penetrate the protective layer and the insulating layer without contacting the insulating layer. This allows stress acting on the insulating layer to be absorbed by the protective layer and not transmitted to the bump part. Through this, the embodiment can further improve the physical reliability and/or electrical reliability of the bump part.

### DESCRIPTION OF DRAWINGS

FIG. 1 is a cross-sectional view illustrating a semiconductor package according to a first embodiment.

FIG. 2 is an enlarged view of a partial region R1 of FIG. 1.

FIG. 3 is a cross-sectional view illustrating a surface roughness of an interface between an insulating layer and a protective layer and a surface roughness of an inner wall of a protective layer in a partial region of FIG. 2.

FIG. 4 is a cross-sectional view illustrating a modified example of the semiconductor package illustrated in FIG. 2.

FIG. 5 is a cross-sectional view illustrating a semiconductor package according to a second embodiment.

FIG. 6 is an enlarged view of a partial region R1 of FIG. 5.

FIG. 7 is a cross-sectional view illustrating a surface roughness of an interface between an insulating layer and a protective layer and a surface roughness of an upper surface of a protective layer in a partial region of FIG. 6.

FIG. 8 is a cross-sectional view illustrating a semiconductor package according to a third embodiment.

FIG. 9 is an enlarged view of a partial region R1 of FIG. 8.

FIG. 10 is a cross-sectional view illustrating a semiconductor package according to a fourth embodiment.

FIGS. 11 to 22 are cross-sectional views illustrating a method for manufacturing a semiconductor package according to a first embodiment illustrated in FIG. 1 in order of processes.

FIGS. 23 to 30 are cross-sectional views illustrating a method for manufacturing a semiconductor package according to a second embodiment illustrated in FIG. 5 in order of processes.

FIGS. 31 to 36 are cross-sectional views illustrating a method for manufacturing a semiconductor package according to a third embodiment illustrated in FIG. 8 in order of processes.

FIGS. 37 to 41 are cross-sectional views illustrating a method for manufacturing a semiconductor package according to a fourth embodiment illustrated in FIG. 10 in order of processes.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

In addition, the semiconductor device may be an integrated passive device (IPD). In addition, the semiconductor device may be a multilayer ceramic capacitor (MLCC) or a silicon-based capacitor.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Semiconductor Package

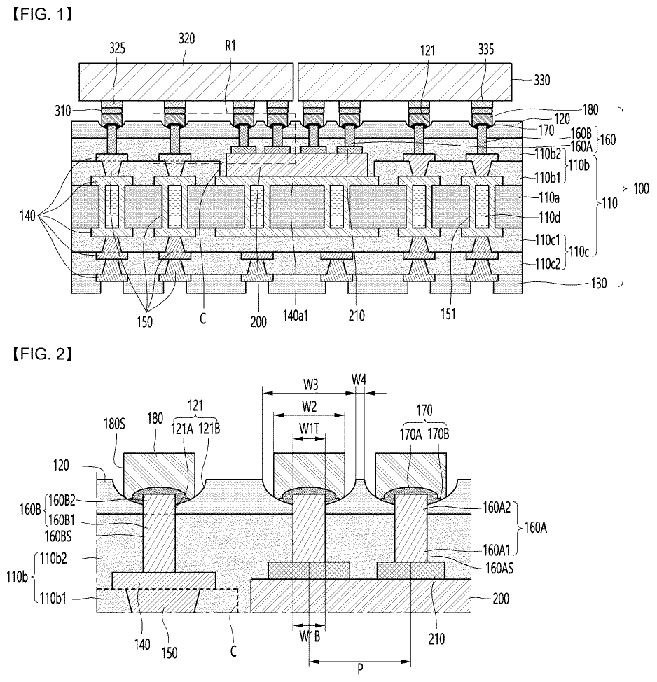

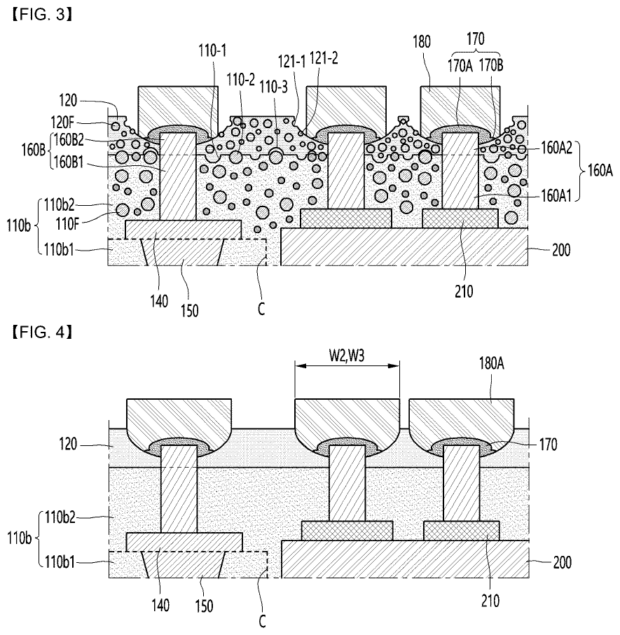

FIG. 1 is a cross-sectional view illustrating a semiconductor package according to a first embodiment, FIG. 2 is an enlarged view of a partial region R1 of FIG. 1, and FIG. 3 is a cross-sectional view illustrating a surface roughness of an interface between an insulating layer and a protective layer and a surface roughness of an inner wall of a protective layer in a partial region of FIG. 2.

Hereinafter, a semiconductor package according to a first embodiment will be described with reference to FIGS. 1 to 4.

Referring to FIG. 1, the semiconductor package includes a circuit board 100, a connection member 200 embedded within the circuit board 100, and a semiconductor device 320, and 330 disposed on the circuit board 100.

In one embodiment, the circuit board 100 means a package substrate. For example, the circuit board 100 is disposed between a main board of the electronic device and the semiconductor device 320 and 330 and can electrically couple them therebetween.

Specifically, the circuit board 100 can horizontally electrically connect the semiconductor devices 320 and 330 and vertically electrically connect the semiconductor devices 320 and 330 and the main board of the electronic device.

In another embodiment, the circuit board 100 means a relay substrate disposed between the package substrate and the semiconductor device 320 and 330. For example, the relay substrate can mean an interposer. That is, the circuit board 100 can horizontally electrically connect the semiconductor devices 320 and 330 and vertically electrically connect the semiconductor devices 320 and 330 and the package substrate.

The semiconductor package includes a semiconductor device 320 and 330 disposed on the circuit board 100.

The semiconductor device 320 and 330 may include a first semiconductor device 320 and a second semiconductor device 330, but is not limited thereto. For example, three or more semiconductor devices may be disposed on the circuit board, or one semiconductor device may be disposed on the circuit board 100.

The semiconductor package includes a bonding part 310 disposed between the semiconductor device 320 and 330 and the circuit board 100.

The bonding part 310 electrically connects between terminals 325 and 335 of the semiconductor device 320 and 330 and a bump part 180 of the circuit board 100.

The bonding part 310 electrically connects between the electrode part of the circuit board 100 and the terminal 325 and 335 of the semiconductor device 320 and 330 by using at least one bonding method among wire bonding, solder bonding, and direct bonding between metals.

The wire bonding method means electrically connecting the electrode part of the circuit board 100 and the terminal 325 and 335 of the semiconductor device 320 and 330 using a conductor such as gold (Au).

The solder bonding method electrically connects the electrode part of the circuit board 100 and the terminal 325 and 335 of the semiconductor device 320 and 330 using a material containing at least one of Sn, Ag, and Cu.

The direct metal bonding method means applying heat and pressure between the electrode part of the circuit board 100 and the terminal 325 and 335 of the semiconductor device 320 and 330 to recrystallize without the use of solder, wire, conductive adhesive, etc., thereby directly bonding the electrode part of the circuit board 100 and the terminal 325 and 335 of the semiconductor device 320 and 330. In this case, the bonding part 310 may mean a metal layer formed between the electrode part of the circuit board 100 and the terminal 325 and 335 of the semiconductor device 320 and 330 by recrystallization.

For example, the bonding part 310 may electrically connect the electrode part of the circuit board 100 and the terminal 325 and 335 of the semiconductor device 320 and 330 by a thermal compression bonding method. The thermal compression bonding method may reduce a volume of the bonding part 310 and prevent short circuits between multiple bonding parts. Therefore, when the terminal 325 and 335 of the semiconductor device 320 and 330 and/or the bump part 180 of the circuit board 100 have a fine pitch, the thermal compression bonding method may be advantageous.

According to one embodiment, the semiconductor package includes a connection member 200 embedded in the circuit board 100.

The connection member 200 is partially overlapped with the semiconductor devices 320 and 330 disposed on the circuit board in a vertical direction. The connection member 200 may be referred to as an Embedded Interconnection Bridge (EMIB).

The connection member 200 electrically connects a part of the terminal 325 of the first semiconductor device 320 and a part of the terminal 335 of the second semiconductor device 330.

A semiconductor device may be mounted on a circuit board 100 as a functionally separated chiplet unit, or multiple semiconductor devices having different functions, such as a CPU and GPU, or a GPU and HBM, and a connection member 200 may perform the function of horizontally electrically connecting them.

In one embodiment, the connection member 200 is an inorganic bridge. For example, the inorganic bridge may be a silicon bridge. For example, the connection member 200 may include a silicon substrate and a redistribution layer.

In another embodiment, the connection member 200 is an organic bridge. For example, the connection member 200 may include an organic material. For example, the connection member 200 may include an organic substrate in which the silicon substrate of the inorganic bridge is redisposed with an organic substrate.

The connection member 200 includes a plurality of pads 210. The plurality of pads 210 of the connection member 200 is electrically connected to a via electrode of an electrode part of the circuit board 100. In addition, an electrode part 160 of the circuit board 100 is electrically connected to the terminal 325 and 335 of the semiconductor device 320 and 330. Therefore, the connection member 200 electrically connects the terminals 325 and 335 of the semiconductor device 320 and 330.

The circuit board 100 electrically connected to the connection member 200 and the semiconductor device 320 and 330 is specifically described as follows.

The circuit board 100 includes an insulating layer 110.

The insulating layer 110 may include an organic material that does not include a reinforcing member, which has excellent processability, enables slimming of the circuit board, and enables miniaturization of the electrode part provided on the circuit board 100. For example, the insulating layer 110 of the circuit board 100 may use ABF (Ajinomoto Build-up Film), a product released by Ajinomoto Co., Ltd., and FR-4, BT (Bismaleimide Triazine), PID (Photo Image-able Dielectric resin), etc. may be used.

The insulating layer 110 may be provided in a form in which a plurality of are laminated.

For example, as shown in FIG. 1, the insulating layer 110 may have a five-layer structure including first to fifth layers, but is not limited thereto.

In one embodiment, a plurality of layers of the insulating layer 110 may be provided with a same insulating material, but is not limited thereto, and at least one layer among a plurality of layers of the insulating layer 110 may be provided with an insulating material different from at least other layers.

When the insulating layer 110 is provided with a plurality of layers, interfaces between the plurality of layers may not be easily distinguished. In this case, the distinction of the interfaces between the layers may be made by an electrode part disposed in the insulating layer 110. The electrode part of the embodiment includes a first electrode 140 and a second electrode 150. At this time, the first electrode 140 may include a trace or/and pad provided on the circuit board, and may be referred to as a wiring electrode. The second electrode 150 may be referred to as a through electrode or via electrode that penetrates at least one layer of the insulating layer 110.

The first electrode 140 is disposed at an interface between the plurality of layers of the insulating layer 110. The second electrode 150 electrically connects the first electrode 140 disposed in different layers along a vertical direction. At this time, a width of the first electrode 140 in the horizontal direction is different from a width of the second electrode 150 in the horizontal direction. Therefore, a difference between the width of the first electrode 140 and the width of the second electrode 150 in the horizontal direction can be used to distinguish interfaces of a plurality of layers of the insulating layer 110. In addition, a slope of a side surface of the first electrode 140 is different from a slope of a side surface of the second electrode 150. Therefore, a difference between the slope of the side surface of the first electrode 140 and the slope of the side surface of the second electrode 150 can be used to distinguish interfaces of a plurality of layers of the insulating layer 110.

However, even if a plurality of layers of the insulating layer 110 include a same insulating material, the interfaces between them can be distinguished.

Through a laminated structure of the above-described insulating layer 110, the circuit board of the embodiment can electrically connect between the semiconductor device 320 and 330 and the package substrate and/or the main board.

In one embodiment, at least one of a plurality of layers of the insulating layer 110 includes a reinforcement member. In one embodiment, the reinforcement member may refer to glass fiber. In another embodiment, the reinforcement member may refer to GCP (Glass Core Primer). When the reinforcement member refers to glass fiber, at least one of a plurality of layers of the insulating layer 110 serves as a core layer, thereby providing the circuit board 100 with a core substrate.

In addition, the rigidity of the circuit board can be improved by having at least one layer among a plurality of layers of the insulating layer 110 include a reinforcement member. For example, the reinforcement member can function to prevent the circuit board 100 and the semiconductor package from being significantly warped in a specific direction. Therefore, warping of the insulating layer 110 can be prevented during a process of manufacturing the circuit board 100, thereby improving the positional accuracy of the electrode part 140 and, further, enhancing an alignment between them. In addition, the semiconductor devices 320 and 330 can be coupled to the circuit board 100 as the rigidity of the circuit board 100 is secured, and the semiconductor devices 320 and 330 can be operated stably. Furthermore, electronic products such as servers to which the semiconductor package of the embodiment is applied can be operated stably, and thus product reliability can be improved.

For example, the insulating layer 110 may be provided in five layers. In this case, the insulating layer 110 includes a first insulating layer 110a of a core layer including a reinforcement member. In addition, the insulating layer 110 includes a second insulating layer 110b provided on the first insulating layer 110a and including a first layer 110b1 and a second layer 110b2 that do not include a reinforcement member. The insulating layer 110 includes a third insulating layer 110c provided under the first insulating layer 110a and including a third layer 110c1 and a fourth layer 110c2 that do not include a reinforcement member.

In addition, if at least one of the multiple layers of the insulating layer 110 includes a reinforcement member, an insulating member 110d is provided in the first insulating layer 110a that includes the reinforcement member. The insulating member 110d penetrates the first insulating layer 110a that includes the reinforcement member. The insulating member 110d is surrounded by a second electrode 151 penetrating the first insulating layer 110a including the reinforcement member.

That is, when the first insulating layer 110a is thick, a problem may occur in which a second electrode 151 penetrating the first insulating layer 110a cannot densely fill a through hole of the first insulating layer 110a. Accordingly, a problem may occur in which an upper or lower surface of the second electrode 151 cannot be plated flatly, and voids may occur inside the second electrode 151. Therefore, the arrangement of the insulating member 110d may solve electrical reliability problems and/or mechanical reliability problems that may occur when the second electrode 151 does not completely fill the through hole of the layer including the reinforcing member.

The insulating layer 110 has a cavity C. The cavity C can penetrate at least one layer among a plurality of layers of the insulating layer 110. The cavity C provides a space in which the connection member 200 is disposed. The cavity C may be formed in the first layer 110b1 of the second insulating layer 100b of the insulating layer 110, but is not limited thereto. The cavity C may also be formed in the first insulating layer 110a. Furthermore, the cavity C may be formed by commonly penetrating at least two insulating layers. In this case, if an insulating layer including the cavity C and other insulating layers disposed on the insulating layer including the cavity C includes a same insulating material, the sidewalls of the cavity C may not be distinguished.

The circuit board 100 includes a protective layer.

That is, the circuit board 100 includes a first protective layer 120 disposed on the insulating layer 110. The first protective layer 120 is disposed on an uppermost insulating layer among a plurality of layers of the insulating layer 110. For example, the first protective layer 120 may be disposed on the second layer 110b2 of the second insulating layer 110b.

Furthermore, the circuit board 100 includes a second protective layer 130 disposed under the insulating layer 110. The second protective layer 130 is disposed under a lowermost insulating layer among a plurality of layers of the insulating layer 110. For example, the second protective layer 130 may be disposed under the fourth layer 110c2 of the third insulating layer 110c.

The first protective layer 120 and the second protective layer 130 may be solder resist layers including an organic polymer material. For example, the first protective layer 120 and the second protective layer 130 may include an epoxy acrylate resin. In detail, the first protective layer 120 and the second protective layer 130 may include resin, a curing agent, a photo initiator, pigments, solvents, fillers, additives, acrylic monomers, and the like. However, the embodiment is not limited thereto, and the first protective layer 120 and the second protective layer 130 may be any one of a photo solder resist layer, a cover-lay, and a polymer material.

Each of the first protective layer 120 and the second protective layer 130 includes a through hole.

For example, the first protective layer 120 includes a through hole 121 penetrating upper and lower surfaces of the first protective layer 120. Furthermore, the second protective layer 130 includes a through hole penetrating upper and lower surfaces of the second protective layer 130.

The through hole 121 of the first protective layer 120 is divided into a plurality of parts.

That is, referring to FIG. 2, the through hole 121 of the first protective layer 120 includes a first part 121A adjacent to a lower surface of the first protective layer 120. Furthermore, the through hole 121 of the first protective layer 120 includes a second part 121B adjacent to an upper surface of the first protective layer 120.

An inner wall of the first part 121A and the inner wall of the second part 121B of the through hole 121 of the first protective layer 120 have different slopes.

The first part 121A of the through hole 121 of the first protective layer 120 is in contact with the electrode part of the circuit board. That is, the inner wall of the first part 121A of the through hole 121 of the first protective layer 120 is in contact with the via electrode 160. Accordingly, the inner wall of the first part 121A of the through hole 121 of the first protective layer 120 has a slope corresponding to a slope of a side surface 160S of the via electrode 160. For example, the inner wall of the first part 121A of the through hole 121 of the first protective layer 120 may have a slope that is perpendicular to the upper surface and/or the lower surface of the first protective layer 120. Here, having a perpendicular slope may mean that a slope of the inner wall of the first part 121A has a range of 85 degrees to 95 degrees with respect to the upper surface and/or the lower surface of the first protective layer 120. Accordingly, an upper width and a lower width of the first part 121A of the through hole 121 of the first protective layer 120 may be substantially the same. For example, the inner wall of the first part 121A of the through hole 121 of the first protective layer 120 may have a slope whose width does not change from an upper end to a lower end. In addition, a via electrode 160 is disposed in the first part 121A of the through hole 121 of the first protective layer 120.

The second part 121B of the through hole 121 of the first protective layer 120 is disposed on the first part 121A. For example, the second part 121B of the through hole 121 of the first protective layer 120 is positioned between the upper surface of the first protective layer 120 and the first part 121A.

The second part 121B of the through hole 121 of the first protective layer 120 does not contact the via electrode 160. For example, at least a portion of the second part 121B of the through hole 121 of the first protective layer 120 overlaps the via electrode 160 in the horizontal direction and does not contact the via electrode 160.

The inner wall of the second part 121B of the through hole 121 of the first protective layer 120 has a different slope than the inner wall of the first part 121A. The second part 121B of the through hole 121 of the first protective layer 120 has a slope whose width changes from an upper end to a lower end. For example, the second part 121B of the through hole 121 of the first protective layer 120 has a slope whose width decreases from an upper end to a lower end.

The inner wall of the second part 121B of the through hole 121 of the first protective layer 120 may have a specific curvature. For example, the second part 121B of the through hole 121 of the first protective layer 120 has a curved surface with a specific curvature whose width decreases from an upper end to a lower end. At least a portion of the inner wall of the second part 121B of the through hole 121 of the first protective layer 120 is in contact with the metal layer 170 provided on the via electrode 160. Therefore, at least a portion of the lower surface of the metal layer 170 may have a curved surface corresponding to the inner wall of the second part 121B. In addition, at least another portion of the inner wall of the second part 121B of the through hole 121 of the first protective layer 120 is in contact with the bump part 180. Therefore, at least a portion of a lower surface of the bump part 180 may have a curved surface corresponding to the inner wall of the second part 121B.

The first part 121A and the second part 121B of the through hole 121 of the first protective layer 120 may be formed in different methods, and thus may have different slopes.

The first protective layer 120 is laminated while the via electrode 160 is disposed. Accordingly, the first part 121A of the first protective layer 120 can be formed to correspond to a region where the via electrode 160 is disposed. That is, the inner wall of the first part 121A of the first protective layer 120 has a slope corresponding to the slope of the side surface 160S of the via electrode 160.

The second part 121B of the first protective layer 120 is formed by performing a process of thinning a thickness of a partial region of the first protective layer 120. For example, the second part 121B of the first protective layer 120 can be formed by performing a process of thinning the thickness of a partial region of the first protective layer 120 using an etchant capable of etching the first protective layer 120. At this time, the second part 121B does not entirely penetrate the upper and lower surfaces of the first protective layer 120. For example, the second part 121B penetrates a partial region of the first protective layer 120 from the upper surface of the first protective layer 120 toward the lower surface of the first protective layer 120. Therefore, an inner wall of the second part 121B may have a curved surface by performing a process of thinning the thickness using an etchant.

At this time, the first protective layer 120 has a plurality of through holes 121 spaced apart in a horizontal direction. Among the plurality of through holes 121, through holes that do not overlap with the connection member 200 in a vertical direction do not require a fine width and fine pitch. This is because a bump part connected to a terminal of a semiconductor device having a relatively large width and large spacing is disposed in the through hole 121 that does not overlap with the connection member 200 in a vertical direction. In contrast, a bump part connected to a terminal of a semiconductor device with a relatively fine width and spacing is disposed in the through hole of the first protective layer 120 that overlaps the connection member 200 in a vertical direction. Therefore, a through hole of the first protective layer 120 that overlaps the connection member 200 in a vertical direction requires a fine width and spacing. Accordingly, the following describes a width and spacing of the through hole 121 that overlaps the connection member 200 in a vertical direction among a plurality of through holes provided in the first protective layer 120.

A width W1T of the first part 121A of the through hole 121 of the first protective layer 120 in a horizontal direction is equal to a width W1T of the via electrode 160 in a horizontal direction. The width W1T of the first part 121A of the through hole 121 of the first protective layer 120 in the horizontal direction may range from 7 μm to 20 μm.

If the width W1T of the first part 121A in the horizontal direction is less than 7 μm, the width W1T of the via electrode 160 in the horizontal direction may also be less than 7 μm, thereby preventing the via electrode 160 from penetrating a partial region of the first protective layer 120 together with the insulating layer 110. If the width W1T of the first part 121A in the horizontal direction is less than 7 μm, the physical reliability and/or electrical reliability of the via electrode 160 may deteriorate, thereby deteriorating the operational reliability of the semiconductor package. If a width W1T of the first part 121A in a horizontal direction is less than 7 μm, the allowable current of the signal that can be transmitted through the via electrode 160 may decrease, thereby deteriorating the electrical characteristics of the semiconductor package.

If the width W1T of the first part 121A in a horizontal direction exceeds 20 μm, the second part 121B provided on the first part 121A may not have a desired width W3 in a horizontal direction. If the width W1T of the first part 121A in a horizontal direction exceeds 20 μm, it may be difficult to adjust a horizontal distance P1 between centers of two adjacent bump parts to 40 μm or less. If the width W1T of the first part 121A in the horizontal direction exceeds 20 μm, a spacing W4 between two adjacent through holes 121 may not have a target value. Furthermore, if the spacing W4 between two adjacent through holes 121 does not have the target value, diffusion and/or overflow of the bonding part 310 may occur, resulting in an electrical short circuit problem in which two adjacent bonding parts are electrically connected to each other.

A width W3 of the second part 121B of the through hole 121 of the first protective layer 120 is greater than a width W1T of the first part 121A. Here, the width W3 of the second part 121B may refer to a width of a region of the second part 121B that is closest to an upper surface of the first protective layer 120. For example, the width W3 of the second part 121B may refer to a width of a region having a largest width among all regions in a thickness direction of the second part 121B. For example, the width W3 of the second part 121B may refer to a maximum width of the second part 121B.

The width W3 of the second part 121B may have a range of 24 μm to 30 μm. If the width W3 of the second part 121B is less than 24 μm, a depth of the second part 121B (e.g., a vertical distance from an upper surface of the first protective layer to an upper end of the first part) may not have a certain level. For example, if the width W3 of the second part 121B is less than 24 μm, the upper surface of the via electrode 160 may not be exposed through the second part 121B, and thus, electrical reliability with the semiconductor device may be deteriorated. If the width W3 of the second part 121B is less than 24 μm, at least a portion of the second part 121B may not overlap the via electrode 160 in the horizontal direction. In this case, a contact area between the via electrode 160 and the metal layer 170 and/or the bump part 180 may be reduced, and thus, a problem of the metal layer 170 and/or the bump part 180 being peeled off from the via electrode 160 may occur.

If the width W3 of the second part 121B exceeds 30 μm, it may be difficult to adjust the horizontal distance P1 between the centers of two adjacent bump parts to 40 μm or less. If the width W3 of the second part 121B exceeds 30 μm, the spacing W4 between two adjacent through holes may not have a target value. In addition, if the spacing W4 between two adjacent through holes does not have the target value, diffusion and/or overflow of the bonding part 310 may occur, and thus an electrical short circuit problem in which two adjacent bonding parts are electrically connected to each other may occur.

The through holes 121 of the first protective layer 120 are provided in multiple numbers and are spaced apart in the horizontal direction, and the spacing W4 between two adjacent through holes has a range of 10 μm to 16 μm. The spacing W4 refers to a spacing between the second parts of each of two adjacent through holes. If the spacing W4 between two through holes is less than 10 μm, the second parts of two adjacent through holes may be connected to each other due to a process deviation in a process of forming the second part 121B of the through hole 121. If the spacing W4 between two through holes exceeds 16 μm, it may be difficult to maintain the horizontal distance P1 between the centers of two adjacent bump parts to 40 μm or less.

The embodiment can design the horizontal distance P1 between the centers of a plurality of bump parts to be 40 μm or less by controlling the width and spacing of the through holes 121 provided in the first protective layer 120. Thus, the embodiment can improve circuit integration and miniaturize the circuit board and semiconductor package. Furthermore, the embodiment can reduce the distance between a plurality of bump parts 180, thereby minimizing a transmission distance of signals transmitted through the corresponding bump parts. Therefore, the embodiment can minimize signal transmission loss that increases with signal transmission distance, thereby improving communication characteristics of the circuit board and semiconductor package. In addition, the embodiment can allow a semiconductor device disposed on a circuit board to operate stably, thereby allowing an electronic product such as a server to which a semiconductor package is applied to operate stably.

The circuit board 100 includes an electrode part. The electrode part includes a first electrode 140 and a second electrode 150, which are distinguished by their location and function.

The first electrode 140 can be horizontally disposed between each of a plurality of layers of the insulating layer 110, and the second electrode 150 can be vertically disposed to penetrate each of a plurality of layers of the insulating layer 110.

The first electrode 140 includes a dummy electrode 140a1. The dummy electrode 140a1 overlaps the connection member 200 in the vertical direction. The dummy electrode 140a1 is connected to the connection member 200. For example, an adhesive member may be provided between the dummy electrode 140a1 and the connection member 200, and the connection member 200 may be attached to the dummy electrode 140a1 by the adhesive member. The dummy electrode 140a1 may have a heat dissipation function that dissipate heat generated through the connection member 200. Therefore, among the through electrodes that penetrate the first insulating layer 110a, the through electrode that overlaps the dummy electrode 140a1 in the vertical direction may function as a heat dissipation electrode that dissipate heat generated in the connection member 200 to an outside. Through this, the embodiment can efficiently dissipate heat generated in the connection member 200. Accordingly, the embodiment can enable the semiconductor device 320 and 330 to operate more stably, thereby improving operating characteristics.

The second electrode 150 is provided within a through hole penetrating each layer of the insulating layer 110. The second electrode 150 may be referred to as a through electrode or a via electrode. At this time, the second electrode 150 includes a via electrode 160 positioned higher than the connection member 200.

The via electrode 160 penetrates at least a partial region of the insulating layer 110. Preferably, the via electrode 160 penetrates an insulating layer disposed on the connection member 200 among a plurality of layers of the insulating layer 110. For example, the via electrode 160 penetrates at least a portion of the second layer 110b2 of the second insulating layer 110b.

A height of an upper surface of the via electrode 160 may be greater than a height of an upper surface of the insulating layer 110. The via electrode 160 may be provided so as to protrude on the insulating layer 110. That is, the embodiment may perform a process of stacking the insulating layer 110 and a process of thinning the thickness of the stacked insulating layer 110 while the via electrode 160 is disposed. Through this, at least a portion of the via electrode 160 may be made to protrude on the insulating layer 110, and further, the via electrode 160 may be made to penetrate at least a portion of the first protective layer 120.

A plurality of via electrodes 160 are provided and are spaced apart from each other in the horizontal direction. The via electrode 160 includes a first via electrode 160A that vertically overlaps the connection member 200. In addition, the via electrode 160 includes a second via electrode 160B that overlaps the first via electrode 160A in a horizontal direction but does not vertically overlap the connection member 200.

At this time, the second via electrode 160B that does not overlap the connection member 200 in a vertical direction may not require a fine width or fine pitch. This is because a bump part connected to a terminal of a semiconductor device with a relatively large width and large spacing is disposed on the second via electrode 160B that does not overlap the connection member 200 in a vertical direction. In contrast, a bump part connected to a terminal of a semiconductor device with a relatively small width and small spacing is disposed on the first via electrode 160A that vertically overlaps the connection member 200. Therefore, the first via electrode 160 that overlaps the connection member 200 in a vertical direction requires a fine width and small spacing.

Among the plurality of via electrodes 160, the first via electrode 160A that overlaps the connection member 200 in the vertical direction may have the width and horizontal distance described below. In this case, the second via electrode 160B that does not overlap the connection member 200 in the vertical direction in one embodiment may have a same width as the first via electrode 160A that overlaps the connection member 200 in the vertical direction. However, the embodiment is not limited thereto. For example, the second via electrode 160B that does not overlap the connection member 200 in the vertical direction in another embodiment may have a larger width than the first via electrode 160A.

Preferably, the first via electrode 160A and the second via electrode 160B are formed in a same method, and thus may have a same shape and a same size (for example, a same width). Through this, the embodiment can minimize a difference in current amount that occurs in a process of plating the first via electrode 160A and the second via electrode 160B, respectively. For example, when the first via electrode 160A and the second via electrode 160B have different widths, a difference in current amount may occur in a process of plating the first via electrode 160A and the second via electrode 160B, respectively. Therefore, a height of the via electrode having a relatively small width may be greater than a height of a via electrode having a relatively large width, and thus a height deviation may occur. Accordingly, the embodiment can make the first via electrode 160A and the second via electrode 160B have a same width, thereby minimizing a height difference between the first via electrode 160A and the second via electrode 160B. Accordingly, the embodiment can make the first via electrode 160A and the second via electrode 160B have a same height. Accordingly, the embodiment can allow the bump parts 180 respectively disposed on the first via electrode 160A and the second via electrode 160B to have a same height. Therefore, the embodiment can allow the semiconductor device to be stably mounted on the bump part 180, thereby improving the operating characteristics of the semiconductor device.

That is, the via electrode 160 may be provided to penetrate at least a portion of the insulating layer 110 and at least a portion of the first protective layer 120.

For example, the first via electrode 160A includes a first electrode part 160A1 penetrating at least a portion of the insulating layer 110 and a second electrode part 160A2 disposed on the first electrode part 160A1 and penetrating at least a portion of the first protective layer 120. Correspondingly, the second via electrode 160B includes a first electrode part 160B1 penetrating at least a portion of the insulating layer 110 and a second electrode part 160B2 disposed on the first electrode part 160B1 and penetrating at least a portion of the first protective layer 120.

The first electrode part 160A1 and the second electrode part 160A2 of the first via electrode 160A may have a same width in the horizontal direction. For example, the first via electrode 160A may have a column shape in which upper and lower surfaces have the same width.

Furthermore, the first electrode part 160B1 and the second electrode part 160B2 of the second via electrode 160B may have the same width in the horizontal direction. For example, the second via electrode 160B may have a column shape in which upper and lower surfaces have the same width.

A portion of a side surface of the second electrode part 160A2 of the first via electrode 160A may contact the first protective layer 120. For example, a portion of the side surface of the second electrode part 160A2 of the first via electrode 160A may contact the inner wall of the first part 121A of the through hole 121 of the first protective layer 120.

Furthermore, a portion of the side surface of the second electrode part 160B2 of the second via electrode 160B may contact the first protective layer 120. For example, a portion of the side surface of the second electrode part 160B2 of the second via electrode 160B may contact the inner wall of the first part 121A of the through hole 121 of the first protective layer 120.

Furthermore, at least a portion of the side surface of each of the first via electrode 160A and the second via electrode 160B may overlap with the first protective layer 120 in the horizontal direction without contacting the first protective layer 120.

Accordingly, the embodiment can allow at least a portion of the metal layer 170 to surround each side surface of the first via electrode 160A and the second via electrode 160B. Accordingly, the embodiment can increase the contact area between the via electrode 160 including the first via electrode 160A and the second via electrode 160B and the metal layer 170, thereby improving the adhesion between the via electrode 160 and the metal layer 170. Accordingly, the embodiment can prevent cracks from occurring at an interface between the via electrode 160 and the metal layer 170 due to stress generated by expansion and/or contraction of the first protective layer 120, thereby improving electrical reliability and/or physical reliability.

A width W1T of the upper surface and a width W1B of the lower surface of the first via electrode 160A may correspond to or be identical to each other. The width W1T of the upper surface and the width W1B of the lower surface of the second via electrode 160B may correspond to or be identical to each other.

In this case, the width W1T of the upper surface and the width W1B of the lower surface being identical to each other may mean that the width W1T of the upper surface satisfies a range of 90% to 110%, 95% to 105%, 96% to 104%, or 97% to 103% of the width W1B of the lower surface.

That is, each of the first via electrode 160A and the second via electrode 160B of the embodiment may be formed by filling an opening provided in a dry film with a conductive material. Accordingly, the width W1T of the upper surface and the width W1B of the lower surface of each of the first via electrode 160A and the second via electrode 160B may correspond to or be identical to each other.

The side surface 160AS of the first via electrode 160A may be perpendicular to the upper or lower surface of the first via electrode 160A. Furthermore, the side surface 160BS of the second via electrode 160B may be perpendicular to the upper or lower surface of the second via electrode 160B.

Here, “perpendicular” may mean that the slope of the side surface 160S relative to the upper or lower surface ranges from 85 degrees to 95 degrees.

That is, via electrodes according to the prior art are formed by filling a through hole in an insulating layer with a conductive material using a laser process. At this time, when forming a through hole using a laser process, a slope of an inner wall of the through hole has a slope that narrows from top to bottom due to the characteristics of a Gaussian beam. That is, a through hole according to the prior art has a curved portion whose width narrows rapidly along the vertical direction. At this time, since the width of the bump part is relatively small, stress may be applied to the curved portion due to the heat cycle of the protective layer caused by the heat generated during the operation of the semiconductor device or due to a subsequent process, which may cause a crack to occur at the interface between the bump part and the first electrode, or a reliability issue may occur in which the bump part is peeled off from the first electrode. To solve this, when a width of the bump part is increased, it may be difficult to adjust a pitch between a plurality of bonding parts to 40 μm or less, and accordingly, an area of the semiconductor package may increase and thus it may be difficult to reduce the thickness. Furthermore, when forming a through hole using a laser process, the process time may increase, which may reduce productivity. Furthermore, when a through hole having a relatively small width is formed through a laser process, it may be difficult to align the laser beams at a correct position, and accordingly, defects such as misalignment of the through hole may occur, thereby deteriorating product yield.

In addition, a slope of the via electrode positioned within the through hole gradually decreases from the upper surface to the lower surface. Accordingly, the width of the upper surface of the via electrode according to the prior art differs from the width of the lower surface. Therefore, the via electrode according to the prior art has a limitation in reducing the size of the via electrode due to the difference between the width of the upper surface and the width of the lower surface. For example, the width of the upper surface of the via electrode according to the prior art is larger than the width W1T of the upper surface of the via electrode 160 according to the embodiment. Accordingly, the width of the bump part disposed on the via electrode of the prior art is also larger than the width of the bump part 180 according to the embodiment. As a result, the horizontal distance between the centers of the adjacent bump parts of the prior art exceeds 50 μm.

In contrast, the via electrode 160 according to the embodiment is formed by filling an opening provided in a dry film with a conductive material, whereby the width W1T of the upper surface and the width W1B of the lower surface may correspond to or be identical to each other. Accordingly, the embodiment can reduce the width of the via electrode 160 compared to the comparative example. Furthermore, the embodiment can reduce the width of the bump part 180 disposed on the via electrode 160 compared to the comparative example. Furthermore, the embodiment can allow the horizontal distance P1 between the centers of two adjacent bump parts to be 40 μm or less.

Therefore, the embodiment can reduce the signal transmission distance between a plurality of semiconductor devices, thereby minimizing signal transmission loss. Therefore, the embodiment can improve the communication characteristics of the circuit board and the semiconductor package. Furthermore, the embodiment can allow the semiconductor device disposed on the circuit board to operate stably, thereby ensuring that electronic products such as servers to which the semiconductor package is applied operate stably.

In addition, the embodiment may have a second electrode part 160A2 and 160B2 in which the via electrode 160 penetrates at least a portion of the first protective layer 120, and the width of the first electrode part 160A1 and 160B1 and the second electrode part 160A2 and 160B2 may have corresponding or identical widths. Accordingly, the embodiment may eliminate a via land part (e.g., annual ring) provided on the via electrode and having a width greater than that of the via electrode. Accordingly, the embodiment may further reduce the width and pitch of the via electrode 160, and further reduce the width and pitch of the bump part 180 disposed on the via electrode 160.

A width of the via electrode 160, including the first via electrode 160A and the second via electrode 160B, may range from 7 μm to 20 μm. For example, the width W1T of the upper surface and the width W1B of the lower surface of the via electrode 160 may correspond to or be identical to each other, and thus, the width W1T of the upper surface and the width W1B of the lower surface may each range from 7 μm to 20 μm.

If the width of the via electrode 160 is less than 7 μm, the via electrode 160 may not penetrate a partial region of the first protective layer 120 together with the insulating layer 110. For example, if the width of the via electrode 160 is less than 7 μm, the physical and/or electrical reliability of the via electrode 160 may deteriorate, thereby deteriorating the operational reliability of the semiconductor package. If the width of the via electrode 160 is less than 7 μm, the allowable current of the signal that can be transmitted through the via electrode 160 may decrease, thereby deteriorating the electrical characteristics of the semiconductor package.

If the width of the via electrode 160 exceeds 20 μm, the width of the bump part 180 may increase, or the width W3 of the second part 121B of the through hole 121 provided in the first protective layer 120 may increase. Consequently, it may be difficult to maintain the horizontal distance P1 between the centers of two adjacent bump parts to 40 μm or less.

Furthermore, the circuit board 100 includes a metal layer 170 disposed on the via electrode 160.

The metal layer 170 may be provided to surround at least a portion of the side surface 160S of the via electrode 160. For example, a metal layer 170 may be formed to surround a side surface of the via electrode 160 that does not contact the first protective layer 120.

The metal layer 170 may include a different metal material than the bump part 180. For example, the bump part 180 may include copper, and the metal layer 170 may include nickel, which is a metal material different from that of the bump part 180.

The metal layer 170 may enhance the bonding strength between the via electrode 160 and the bump part 180. For example, if the bump part 180 is disposed directly on the via electrode 160, oxidation of the via electrode 160 may occur, which may deteriorate the bonding strength between the via electrode 160 and the bump part 180. Therefore, the metal layer 170 can prevent oxidation of the via electrode 160 while enhancing the bonding strength between the via electrode 160 and the bump part 180. In addition, the metal layer 170 can solve the reliability problem in which the bump part 180 is peeled off from the via electrode 160 by stress applied during contraction and expansion due to thermal stress of the first protective layer 120.

Furthermore, if the metal layer 170 contains nickel, the adhesion between the via electrode 160 and the bump part 180 can be further enhanced. Furthermore, if electrical connection between the bump part 180 and the semiconductor device is subsequently achieved using a material such as solder, Solder may be diffused to form an inter-metallic compound, and mechanical and electrical reliability of the inter-metallic compound may be deteriorated. In particular, if the bump part 180 contains copper, the problem of forming the inter-metallic compound can be further exacerbated. However, if the metal layer 170 contains nickel, the diffusion of solder can be prevented, thereby preventing the formation of the inter-metallic compound, thereby improving the electrical and mechanical reliability of the semiconductor package.

The lower surface of the metal layer 170 may include a convex curved surface toward the insulating layer 110. For example, at least a portion of the lower surface of the metal layer 170 may have a curved surface corresponding to the inner wall of the second part 121B of the through hole 121 of the first protective layer 120.

Furthermore, the metal layer 170 includes a first portion 170A surrounding upper and side surfaces of the via electrode 160. In addition, the metal layer 170 may further include a second portion 170B extending from the first portion 170A along the inner wall of the second part 121B of the through hole 121 of the first protective layer 120. Through this, the embodiment can more effectively prevent the formation of an inter-metallic compound. Furthermore, the embodiment can further increase the contact area between the bump part 180 and the metal layer 170, thereby improving the adhesion between the bump part 180 and the metal layer 170.

In addition, the circuit board 100 includes the bump part 180. The bump part 180 is disposed on the via electrode 160. Preferably, the bump part 180 is disposed on the metal layer 170 which is disposed on the via electrode 160.

The bump part 180 penetrates at least a portion of the first protective layer 120. For example, the bump part 180 is provided in the second part 121B of the through hole 121 of the first protective layer 120. In addition, an upper surface of the bump part 180 is positioned higher than the upper surface of the first protective layer 120. For example, the bump part 180 is provided to protrude on the first protective layer 120.

That is, the bump part 180 protrudes on the first protective layer 120 of the circuit board 100 to stably bond with the terminals 325 and 335 of the semiconductor device 320 and 330 using the bonding part 310. The bump part 180 maintains a certain distance between the bonding part 310 and the circuit board 100, thereby improving a positional alignment between the bump part 180 and the terminals of the semiconductor device 320 and 330.

The bump part 180 may be a post bump connected to the semiconductor device.

That is, as a width and pitch of terminals of the semiconductor device bonded to the circuit board become smaller, when mounting the semiconductor device using a conductive adhesive such as solder, a conductive adhesive may diffuse along in a horizontal direction, which may cause a plurality of conductive adhesives to become interconnected. For example, the embodiment may perform thermal compression bonding to reduce the volume of the conductive adhesive. However, if the bump part 180 is not provided, there may be difficulties in reducing the volume of the conductive adhesive. This may be because a height of the electrode on which the conductive adhesive is disposed is lower than an upper surface of the first protective layer 120, and thus, the volume of the conductive adhesive increases by a difference between the height of the electrode and the height of the first protective layer 120.

In particular, as the width and pitch of the terminals 325 and 335 of the semiconductor devices 320 and 330 are becoming increasingly smaller, and when a conductive adhesive such as solder is applied to mount the semiconductor devices 320 and 330 without the bump part 180, a spacing between the conductive adhesives may become smaller, resulting in a short circuit problem where two adjacent conductive adhesives are connected to each other. Accordingly, the embodiment includes a bump part 180, and performs a process of mounting a semiconductor device 320 and 330 by applying a conductive adhesive, such as solder, onto the bump part 180. Preferably, the embodiment may perform thermal compression bonding using the bump part 180 protruding toward an outermost side of the circuit board 100. Accordingly, the embodiment can stably mount the semiconductor device on the circuit board, thereby enabling the semiconductor device to operate stably.

The bump part 180 is respectively disposed on the first via electrode 160A and the second via electrode 160B. At this time, the bump part disposed on the first via electrode 160A and the bump part disposed on the second via electrode 160B may have a same width and height. Therefore, they will be collectively referred to as ‘bump part 180’.

The embodiment may allow a plurality of bump parts 180 to have a same height. However, if the plurality of bump parts 180 have height differences, a problem may occur where the semiconductor device is coupled to the bump part 180 in an inclined state. In addition, if the height differences are as described above, a bump part positioned relatively high may be electrically connected to the semiconductor device, but a bump part positioned relatively low may not be electrically connected to the semiconductor device. Conversely, a bump part positioned relatively low may be electrically connected to the semiconductor device, but a bump part positioned relatively high may not be electrically connected to the semiconductor device. Accordingly, the operation of the semiconductor device may not be smoothly performed, and furthermore, the operation of the electronic product or server may not be smoothly performed.

Furthermore, the circuit board may perform impedance matching by adjusting the width or thickness of the electrode part and/or the bump part. At this time, if a height difference occurs due to plating deviations between a plurality of bump parts, impedance matching may not be achieved properly, and electrical reliability issues in the semiconductor package may arise due to impedance mismatching.

Therefore, the embodiment can allow a plurality of bump parts to have the same size, thereby minimizing the height difference between the plurality of bump parts and improving impedance matching reliability.

The bump part 180 is positioned on the metal layer 170. The bump part 180 is disposed within the second part 121B of the through hole 121 of the first protective layer 120.

A lower surface of the bump part 180 is in contact with the inner wall of the second part 121B of the through hole 121 of the first protective layer 120. Accordingly, the lower surface of the bump part 180 may have a curved surface corresponding to the curved surface of the inner wall of the second part 121B of the through hole 121 of the first protective layer 120.

The bump part 180 may be provided to fill a portion of the second part 121B of the through hole 121 of the first protective layer 120. That is, the bump part 180 may have a width W2 smaller than a width W3 of the second part 121B of the through hole 121 of the first protective layer 120. In addition, the bump part 180 may have a width W2 larger than the width W1T of the upper surface and the width W1B of the lower surface of the via electrode 160.

The width W3 of the bump part 180 may satisfy a range of 10 μm to 25 μm. If the width W3 of the bump part 180 is less than 10 μm, the contact area between the bump part 180 and the bonding part 310 decreases, and thus, the semiconductor device may not be stably bonded to the bump part 180. For example, if the width W3 of the bump part 180 is less than 10 μm, a reliability problem may occur in which a semiconductor device disposed on the bump part 180 becomes electrically and/or physically separated from the bump part 180.

If the width W3 of the bump part 180 exceeds 25 μm, an electrical short circuit problem in which a plurality of adjacent bump parts are electrically connected to each other may occur due to a process deviation in a process of forming the bump part 180.

A slope of the side surface 180S of the bump part 180 may be identical to the slope of the side surface of the via electrode 160. That is, the bump part 180 is formed in a same manner as the formation of the via electrode 160, and accordingly, the slope of the side surface 180S of the bump part 180 may have the same slope as the side surface of the via electrode 160 (preferably, the side surface of each of the first and second via electrodes). For example, the side surface 180S of the bump part 180 may be perpendicular to the upper surface of the bump part 180. Preferably, the side surface 180S of the bump part 180 may have an angle ranging from 85 degrees to 95 degrees with respect to the upper surface of the bump part 180.

According to the first embodiment, the via electrode 160 is formed using a dry film having an opening. In addition, at least one layer of the insulating layer 110 is laminated after the via electrode 160 is formed. At this time, the insulating layer laminated after the via electrode 160 is formed covers the via electrode 160 as a whole. Therefore, the embodiment performs a process of thinning the thickness of at least one layer of the insulating layer 110 so that the via electrode 160 has a lower height than the upper surface. Therefore, the via electrode 160 may protrude above the upper surface of the insulating layer 110 while having an upper surface and a lower surface substantially corresponding or the same width. Thereafter, the embodiment forms a first protective layer 120 on the insulating layer 110 and the via electrode 160. Accordingly, at least a portion of the via electrode 160 is provided to penetrate at least a portion of the first protective layer 120. Therefore, the embodiment can refine the width and pitch of the via electrode 160. Furthermore, the embodiment can refine the width and pitch of the bump part 180 disposed on the via electrode 160. Accordingly, the embodiment can allow the horizontal distance P1 between the centers of two adjacent bump parts 180 to be 40 μm or less.

Accordingly, the embodiment can improve circuit integration and miniaturize the circuit board and semiconductor package. Furthermore, the embodiment can reduce a distance between a plurality of bump parts 180, thereby minimizing the transmission distance of signals transmitted through the corresponding bump parts. Therefore, the embodiment can minimize signal transmission loss that increases with signal transmission distance, thereby improving the communication characteristics of the circuit board and semiconductor package. In addition, an embodiment can allow a semiconductor device disposed on a circuit board to operate stably, allowing electronic products such as servers to which semiconductor packages are applied to operate stably.

In addition, the embodiment can perform a process of thinning at least one layer of the insulating layer 110 and a process of thinning the thickness of a portion of the first protective layer 120, thereby achieving a surface roughness and filler arrangement structure different from those of a comparative example.

Referring to FIG. 3, the insulating layer 110 includes a second insulating layer 110b, which includes a first layer 110b1 and a second layer 110b2. A via electrode 160 penetrates the second layer 110b2 of the second insulating layer 110b. The second layer 110b2 of the second insulating layer 110b includes a plurality of fillers 110F.

At this time, the via electrode 160 is formed before the second layer 110b2 of the second insulating layer 110b is laminated. That is, in a process of manufacturing the circuit board, a process of forming the via electrode 160 is performed before a process of laminating the second layer 110b2 of the second insulating layer 110b.

Accordingly, the via electrode 160 may not contact the filler 110F provided in the second insulating layer 110b.

That is, the via electrode of the comparative example is formed by filling a through hole provided in the insulating layer. When the through hole is formed in the insulating layer, the filler provided in the insulating layer is exposed through the inner wall of the through hole. Therefore, the via electrode of the comparative example contacts the filler provided in the insulating layer. At this time, the filler acts as a factor that deteriorates the electrical characteristics of the via electrode, which may deteriorate the electrical reliability of the via electrode.

In contrast, the embodiment allows the via electrode 160 to be formed without performing a process of forming a through hole in the second layer 110b2 of the second insulating layer 110b. Accordingly, the via electrode 160 of the embodiment may overlap the filler 110F provided in the second layer 110b2 of the second insulating layer 110b in the horizontal direction without contacting the filler 110F. Therefore, the embodiment may improve the electrical characteristics of the via electrode 160.

In addition, unevenness may be provided on an upper surface of the second layer 110b2 of the second insulating layer 110b of the embodiment by performing a process of thinning the thickness. Here, the unevenness may be provided to correspond to the filler 110F provided in the second layer 110b2 of the second insulating layer 110b. The upper surface of the second layer 110b2 of the second insulating layer 110b may refer to an upper surface of the insulating layer 110. Accordingly, the unevenness provided on the upper surface of the second layer 110b2 of the second insulating layer 110b will be described below as the unevenness provided on the upper surface of the insulating layer 110.

The upper surface of the insulating layer 110 has a convex surface that is convex toward the first protective layer 120 and a concave surface that is concave toward the lower surface of the insulating layer 110.

When a process of thinning the thickness of the insulating layer 110 is performed while the via electrode 160 is disposed, the filler 110F provided within the insulating layer 110 may be exposed through the upper surface of the insulating layer 110 or may escape outward from the insulating layer 110.

Therefore, an upper surface of the insulating layer 110 may include a concave surface 110-1 corresponding to a space where the filler 110F escapes. The concave surface 110-1 of the upper surface of the insulating layer 110 may be concave toward the lower surface of the insulating layer 110. The concave surface 110-1 of the upper surface of the insulating layer 110 may have a curvature. Preferably, the concave surface 110-1 of the upper surface of the insulating layer 110 is provided to correspond to the filler 110F, and thus may have a curvature corresponding to the curvature of the filler 110F. At this time, the concave surface 110-1 of the upper surface of the insulating layer 110 may be filled with the first protective layer 120. That is, the lower surface of the first protective layer 120 may have a convex surface corresponding to the concave surface 110-1 of the upper surface of the insulating layer 110.

In addition, the upper surface of the insulating layer 110 includes a convex surface. At this time, the convex surface includes a first convex surface 110-2 provided as the filler 110F is exposed. That is, at least a portion of the filler 110F provided in the insulating layer 110 may be exposed to the upper surface of the insulating layer 110. Therefore, the upper surface of the insulating layer 110 may include a first convex surface 110-2 corresponding to the exposed filler 110F. In addition, the first protective layer 120 may cover the first convex surface 110-2 corresponding to the filler 110F exposed to the upper surface of the insulating layer 110. For example, the lower surface of the first protective layer 120 may include a first concave surface corresponding to the first convex surface 110-2 of the upper surface of the insulating layer 110.

In addition, the insulating layer 110 further includes a second convex surface 110-3 provided along the curvature of the filler 110F. That is, the first convex surface 110-2 is a portion where the filler 110F is exposed, and the second convex surface 110-3 is a portion where the filler 110F is not exposed, but is provided convexly on the upper surface of the insulating layer 110 along the curvature of the filler 110F. In addition, the first protective layer 120 is disposed to cover the second convex surface 110-3 of the insulating layer 110. For example, the lower surface of the first protective layer 120 may have a second concave surface corresponding to the second convex surface 110-3 of the upper surface of the insulating layer 110.

Accordingly, the embodiment can increase the contact area between the insulating layer 110 and the first protective layer 120, thereby improving the adhesion between the insulating layer 110 and the first protective layer 120. Furthermore, the embodiment can provide an interface between the insulating layer 110 and the first protective layer 120 with a concave surface 110-1, a first convex surface 110-2, and a second convex surface 110-3, thereby increasing the surface area of the interface. At this time, the insulating layer 110 can expand and/or contract due to heat generated during the operation of the semiconductor device. At this time, the concave surface 110-1, the first convex surface 110-2, and the second convex surface 110-3 can function to alleviate the degree of expansion of the semiconductor package when expanded due to heat. For example, the concave surface 110-1, the first convex surface 110-2, and the second convex surface 110-3 at the interface may have different heights, and accordingly, a volume deformed upon thermal expansion of the insulating layer 110 and/or the first protective layer 120 may be different. That is, the portion corresponding to the concave surface 110-1 may have a thinner thickness than the portions corresponding to the first convex surface 110-2 and the second convex surface 110-3, and the overall thermal deformation of the semiconductor package can be suppressed due to the difference in thermal expansion rate therebetween. Therefore, the embodiment can prevent a semiconductor device coupled to the upper portion of the semiconductor package from being electrically separated upon thermal expansion, and thereby improve product reliability.

In addition, a process is performed to provide the second part 121B of the through hole 121 in the first protective layer 120. At this time, the second part 121B may be formed through a process of thinning a portion of the first protective layer 120. Furthermore, the inner wall of the second part 121B of the through hole 121 of the first protective layer 120 may have a concave surface and a convex surface due to the process of thinning a portion of the first protective layer 120.

That is, the first protective layer 120 includes a filler 120F. Furthermore, during the process of forming the second part 121B, at least a portion of the filler 110F provided within the first protective layer 120 may be exposed through the inner wall of the second part 121B. Accordingly, the inner wall of the second part 121B may include a concave surface 121-1 corresponding to the portion where the filler 110F provided in the first protective layer 120 has escaped. Furthermore, the inner wall of the second part 121B may include a convex surface 121-2 corresponding to a portion where the filler 110F provided in the first protective layer 120 is exposed and/or a convex portion along the curvature of the filler 110F.

FIG. 4 is a cross-sectional view illustrating a modified example of the semiconductor package illustrated in FIG. 2.

Referring to FIG. 4, features other than the width of the bump part 180A may be substantially the same as the semiconductor package described in FIGS. 2 and 3. Therefore, the following description will focus on the bump part 180A corresponding to a modified example.

At this time, the width of the bump part 180 of FIG. 2 is greater than the width of the via electrode 160 and smaller than the width of the second part 121B of the through hole 121 of the first protective layer 120.

In contrast, a width W2 of the bump part 180A of the modified example may be equal to the width of the second part 121B of the through hole 121 of the first protective layer 120. That is, the width W3 of the bump part 180A may range from 24 μm to 30 μm.

Accordingly, the embodiment can improve the adhesion between the bump part 180A and the first protective layer 120 while ensuring that the horizontal distance P1 between the centers of the plurality of bump parts disposed adjacent to each other is 40 μm or less. Furthermore, the embodiment can increase improve the contact area between the bump part 180A and the bonding part 310, thereby improving the bonding strength between the bump part 180 and the bonding part 310.

Therefore, the width of the bump part of the embodiment may be equal to or smaller than the width of the second part 121B of the through hole 121 of the first protective layer 120 with a curved inner wall.

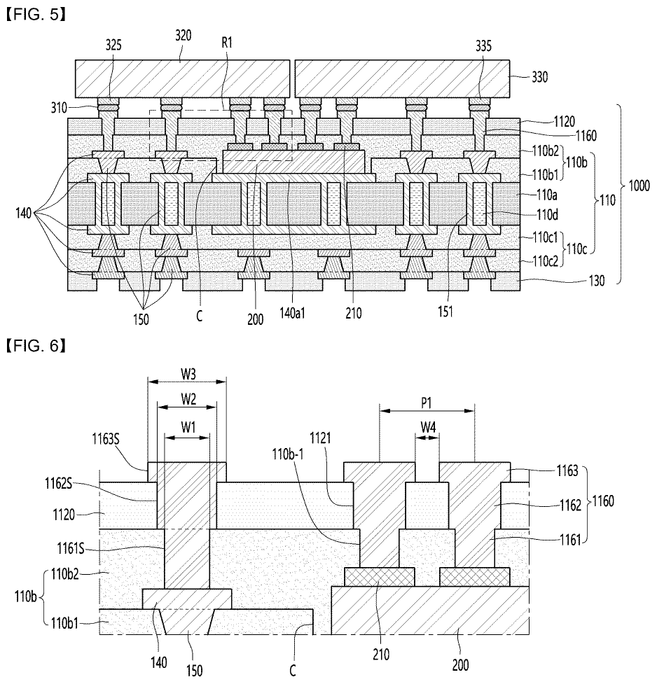

FIG. 5 is a cross-sectional view illustrating a semiconductor package according to a second embodiment, FIG. 6 is an enlarged view of a partial region R1 of FIG. 5, and FIG. 7 is a cross-sectional view illustrating a surface roughness of an interface between an insulating layer and a protective layer and a surface roughness of an upper surface of a protective layer in a partial region of FIG. 6.

The semiconductor package according to the second embodiment may differ from the semiconductor package of the first embodiment illustrated in FIGS. 1 to 4 in structures of the via electrode, the bump part, and the first protective layer. Therefore, detailed descriptions of components having substantially the same characteristics as the semiconductor package of the first embodiment will be omitted below.

Referring to FIGS. 5 and 6, the semiconductor package of the second embodiment includes an insulating layer 110 and a first protective layer 1120 disposed on the insulating layer 110. Furthermore, the semiconductor package includes a bump part 1160 penetrating from the upper surface of the first protective layer 1120 to a partial region of the insulating layer 110. The bump part 1160 may include the via electrode 160 and the bump part 180 provided in the semiconductor package of the first embodiment.

That is, the first embodiment forms the via electrode 160 and the bump part 180 through separate processes. Furthermore, the first embodiment includes a metal layer 170 to improve adhesion between the via electrode 160 and the bump part 180.

In contrast, the second embodiment forms a bump part 1160 penetrating from the upper surface of the first protective layer 1120 to a partial region of the insulating layer 110 through a single process.

The bump part 1160 includes a first through part 1161 penetrating the insulating layer 110. The first through part 1161 is provided to fill the first through hole 110b provided in the insulating layer 110.

The bump part 1160 includes a second through part 1162 disposed on the first through part 1161. The second through part 1162 is provided on the first through part 1161 to penetrate the first protective layer 1120. The second through part 1162 is provided to fill the second through hole 1121 penetrating the upper and lower surfaces of the first protective layer 1120.

The bump part 1160 includes a protruding part 1163 positioned on the second through part 1162. The protruding part 1163 is disposed on the second through part 1162 and protrudes above the upper surface of the first protective layer 1120.

The first through part 1161, the second through part 1162, and the protruding part 1163 of the bump part 1160 are a single metal layer formed through a single plating process.

That is, the second embodiment forms a first through hole 110b-1 in the insulating layer 110 using a first dry film pattern. In addition, the second embodiment forms a second through hole 1121 having a larger width than the first through hole 110b-1 while vertically overlapping the first through hole 110b-1 using a second dry film pattern. Thereafter, the embodiment forms a bump part 1160 filling an opening of the dry film, the first through hole 110b-1, and the second through hole 1121 while arranging a dry film including an opening on the first protective layer 1120. Accordingly, an interface between the first through part 1161, the second through part 1162, and the protruding part 1163 of the bump part 1160 of the second embodiment may not be distinguished. That is, the first through hole 110b-1, the second through hole 1121, and the protruding part 1163 may be formed as a single metal layer and may be formed to penetrate from the upper surface of the first protective layer 1120 to a portion of the insulating layer 110. Therefore, the second embodiment can further improve the adhesion between the first through part 1161, the second through part 1162, and the protruding part 1163 compared to the adhesion between the via electrode 160, the metal layer 170, and the bump part 180 of the first embodiment. Through this, the second embodiment can further improve the electrical reliability and/or mechanical reliability of the bump part 1160.

At this time, the first through part 1161, the second through part 1162, and the protruding part 1163 of the bump part 1160 may have different widths. Accordingly, the side surface of the bump part 1160 may have a step. For example, a side surface 1161S of the first through part 1161, a side surface 1162S of the second through part 1162, and a side surface 1163S of the protruding part 1163 may have a step. Therefore, the second embodiment can efficiently distribute the stress acting due to thermal expansion and/or thermal contraction of the insulating layer 110 and/or the first protective layer 1120. For example, the stress acting due to thermal expansion and/or thermal contraction may not be concentrated in a specific region of the bump part 1160 due to the step of the side surface of the bump part 1160, but may be evenly distributed and acted on the entire region of the bump part 1160. Therefore, the embodiment can solve the reliability problem of cracks occurring in the bump part 1160 due to the stress acting due to thermal expansion and/or thermal contraction. Furthermore, the embodiment can increase the contact area between the bump part 1160 and the insulating layer 110 and the first protective layer 1120 by having a step on the side surface of the bump part 1160, thereby improving the bonding strength between the bump part 1160 and the insulating layer 110 and/or the first protective layer 1120. Therefore, the embodiment can solve the problem of the bump part 1160 being peeled off from the insulating layer 110 and the first protective layer 1120, thereby enabling the semiconductor package to operate stably.

In addition, the upper and lower surfaces of the first through part 1161 of the bump part 1160 may have corresponding or identical widths. This can be achieved by performing a process of laminating the insulating layer 110 in a state in which the first dry film pattern is disposed, thereby forming a first through hole 110b-1 corresponding to a first dry film pattern in the insulating layer 110. Therefore, the embodiment can refine the width and pitch of the first through part 1161 of the bump part 1160 compared to the via electrode of the comparative example provided in the through hole formed through the laser process, and thereby make it possible to make the horizontal distance P1 between the centers of a plurality of adjacent bump parts 1160 40 μm or less. That is, the width of the upper surface of the first through part 1161 can satisfy a range of 90% to 110%, or a range of 95% to 105%, or a range of 96% to 104%, or a range of 97% to 103% of the width of the lower surface of the first through part 1161. In addition, the slope of the side surface 1161S of the first through part 1161 can have a range of 85 degrees to 95 degrees with respect to the upper surface or the lower surface of the first through part 1161.

The width W1 of the first through part 1161 of the bump part 1160 can have a range of 7 μm to 15 μm.

If the width W1 of the first through part 1161 is less than 7 μm, the first through part 1161 may not be able to penetrate the insulating layer 110, and thus, the first through part 1161 may not be electrically connected to the pad 210 of the connection member 200 and/or the first electrode 140. If the width W1 of the first through part 1161 is less than 7 μm, the physical reliability and/or electrical reliability of the first through part 1161 may be deteriorated, and thus, the operational reliability of the semiconductor package may be deteriorated. If the width W1 of the first through part 1161 is less than 7 μm, the allowable current of a signal that can be transmitted through the first through part 1161 may be reduced, and thus, the electrical characteristics of the semiconductor package may be deteriorated. In addition, if the width W1 of the first through part 1161 exceeds 1 5 μm, it may be difficult to adjust the horizontal distance P1 between two adjacent bump parts 1160 to 40 μm or less.

If the width W1 of the first through part 1161 exceeds 15 μm, the side surfaces of the first through part 1161 and the second through part 1162 may not have a step due to a process deviation, and an effect produced by the step may not be achieved.

In addition, the upper and lower surfaces of the second through part 1162 of the bump part 1160 may have corresponding or identical widths. This can be achieved by performing a process of laminating the first protective layer 1120 while the second dry film pattern is disposed, thereby forming a second through hole 1121 corresponding to the second dry film pattern in the first protective layer 1120. Therefore, the embodiment can fine the width and pitch of the second through part 1162 of the bump part 1160 compared to the bump part of the comparative example provided in the through hole formed through the laser process, thereby making it possible to have a horizontal distance P1 between the centers of a plurality of neighboring bump parts 1160 of 40 μm or less. That is, the width of the upper surface of the second through part 1162 can satisfy a range of 90% to 110%, or a range of 95% to 105%, or a range of 96% to 104%, or a range of 97% to 103% of the width of the lower surface of the second through part 1162. In addition, the slope of the side surface 1162S of the second through part 1162 can have a range of 85 degrees to 95 degrees with respect to the upper surface or the lower surface of the second through part 1162. Furthermore, the slope of the side surface 1162S of the second through part 1162 may be the same as the slope of the side surface 1161S of the first through part 1161.

The width W2 of the second through part 1162 of the bump part 1160 may range from 15 μm to 20 μm.

If the width W2 of the second through part 1162 is less than 15 μm, the side surfaces of the first through part 1161 and the second through part 1162 may not have a step due to a process deviation, and the effect produced by the step may not be achieved.

If the width W2 of the second through part 1162 exceeds 20 μm, it may be difficult to maintain the horizontal distance P1 between two adjacent bump parts 1160 to 40 μm or less.

The bump part 1160 includes a protruding part 1163 disposed on a second through part 1162. The protruding part 1163 may have a width greater than that of the second through part 1162, thereby extending in a horizontal direction and disposed on the second through part 1162.

The width W3 of the protruding part 1163 may satisfy a range of 25 μm to 34 μm. If the width W3 of the protruding part 1163 is less than 25 μm, an alignment between the protruding part 1163 and the second through part 1162 in a vertical direction may deteriorate, thereby deteriorating the physical and/or electrical reliability of the bump part 1160. If the width W3 of the protruding part 1163 is less than 25 μm, the contact area with the bonding part 310 may not be secured, thus it may be difficult for the semiconductor device to be stably disposed on the protruding part 1163.

If the width W3 of the protruding part 1163 exceeds 34 μm, it may be difficult to maintain the horizontal distance P1 between two adjacent bump parts 1160 below 40 μm. If the width W3 of the protruding part 1163 exceeds 34 μm, the spacing between the two adjacent bump parts decreases, and accordingly, an electrical short circuit problem in which two adjacent bump parts are electrically connected to each other may occur.

In addition, the spacing W4 between the protruding parts of two adjacent bump parts 1160 that overlap the connection member 200 in a vertical direction may be within a range of 5 μm to 15 μm. If the spacing W4 is less than 5 μm, an electrical short circuit problem in which a plurality of neighboring bump parts are electrically connected to each other may occur due to a process deviation in the process of plating the bump part 1160. Furthermore, if the spacing W4 exceeds 15 μm, it may be difficult to maintain the horizontal distance P1 between the two adjacent bump parts 1160 to 40 μm or less.

Furthermore, the second embodiment may perform a process of thinning the insulating layer 110 during the process of forming the first through hole 110b-1 in the insulating layer 110. Accordingly, the upper surface of the insulating layer 110 has a convex surface that is convex toward the first protective layer 120, and a concave surface that is concave toward the lower surface of the insulating layer 110.

That is, the upper surface of the insulating layer 110 may include a concave surface 110-1 corresponding to a space where the filler 110F has escaped. The concave surface 110-1 of the upper surface of the insulating layer 110 may be concave toward the lower surface of the insulating layer 110. The concave surface 110-1 of the upper surface of the insulating layer 110 may have a curvature. Preferably, the concave surface 110-1 of the upper surface of the insulating layer 110 is provided to correspond to the filler 110F, and thus may have a curvature corresponding to the curvature of the filler 110F. At this time, the concave surface 110-1 of the upper surface of the insulating layer 110 may be filled with a first protective layer 120. That is, the lower surface of the first protective layer 120 may have a convex surface corresponding to the concave surface 110-1 of the upper surface of the insulating layer 110.

In addition, the upper surface of the insulating layer 110 includes a convex surface. At this time, the convex surface includes a first convex surface 110-2 formed as the filler 110F is exposed. That is, at least a portion of the filler 110F formed in the insulating layer 110 may be exposed to the upper surface of the insulating layer 110. Accordingly, the upper surface of the insulating layer 110 may include a first convex surface 110-2 corresponding to the exposed filler 110F. Furthermore, the first protective layer 120 may cover the first convex surface 110-2 corresponding to the filler 110F exposed to the upper surface of the insulating layer 110. For example, the lower surface of the first protective layer 120 may include a first concave surface corresponding to the first convex surface 110-2 of the upper surface of the insulating layer 110.

In addition, the insulating layer 110 further includes a second convex surface 110-3 formed along the curvature of the filler 110F. That is, the first convex surface 110-2 is a portion where the filler 110F is exposed, and the second convex surface 110-3 is a portion where the filler 110F is not exposed and is formed convexly on the upper surface of the insulating layer 110 along the curvature of the filler 110F. Furthermore, the first protective layer 120 is disposed to cover the second convex surface 110-3 of the insulating layer 110. For example, the lower surface of the first protective layer 120 may have a second concave surface corresponding to the second convex surface 110-3 of the upper surface of the insulating layer 110.

Conversely, the inner wall of the first through hole 110b-1 of the insulating layer 110 may not have any unevenness. That is, the first through hole 110b-1 may be formed using the first dry film pattern, and thus, the inner wall of the first through hole 110b-1 may not have any unevenness. Accordingly, a surface roughness of the inner wall of the first through hole 110b-1 may be less than a surface roughness of the upper surface of the insulating layer 110.

In addition, the third embodiment may perform a process of thinning the thickness of the first protective layer 1120 during the process of forming the second through hole 1121 in the first protective layer 1120. Accordingly, the upper surface of the first protective layer 1120 has a convex surface that is convex toward an upper direction, and a concave surface that is concave toward the upper surface of the insulating layer 110.

That is, the upper surface of the first protective layer 1120 may include a concave surface 1120-1 corresponding to a space where the filler 1120F has escaped. The concave surface 1120-1 of the upper surface of the first protective layer 1120 may be concave toward the lower surface of the first protective layer 1120. The concave surface 1120-1 of the upper surface of the first protective layer 1120 may have a curvature. Preferably, the concave surface 1120-1 of the upper surface of the first protective layer 1120 is provided to correspond to the filler 1120F, and thus may have a curvature corresponding to the curvature of the filler 1120F.

In addition, the upper surface of the first protective layer 1120 includes a convex surface. At this time, the convex surface of the first protective layer 1120 includes a first convex surface 1120-2 that is provided as the filler 1120F provided within the first protective layer 1120 is exposed. That is, at least a portion of the filler 1120F provided in the first protective layer 1120 may be exposed to the upper surface of the first protective layer 1120. Accordingly, the upper surface of the first protective layer 1120 may include a first convex surface 1120-2 corresponding to the exposed filler 1120F.

In addition, the first protective layer 1120 further includes a second convex surface 1120-3 formed along the curvature of the filler 1120F. That is, the first convex surface 1120-2 of the first protective layer 1120 is a portion where the filler 1120F is exposed, and the second convex surface 1120-3 is a portion where the filler 1120F is not exposed, but is formed convexly on the upper surface of the first protective layer 1120 along the curvature of the filler 1120F.

In addition, the inner wall of the second through hole 1121 of the first protective layer 1120 may not be formed with unevenness. That is, the second through hole 1121 may be formed using the second dry film pattern, and thus, the inner wall of the second through hole 1121 may not have unevenness. Accordingly, a surface roughness of the inner wall of the second through hole 1121 may be smaller than a surface roughness of the upper surface of the first protective layer 1120.

Furthermore, the first through hole 110b-1 and the second through hole 1121 may be formed using the first and second dry film patterns, and thereby, the filler 110F provided in the insulating layer 110 may not be exposed through the first through hole 110b-1, and the filler 1120F provided in the first protective layer 1120 may not be exposed through the second through hole 1121. Accordingly, the first through part 1161 and the second through part 1162 of the bump part 1160 may not contact the fillers, thereby improving the electrical characteristics of the bump part 1160.

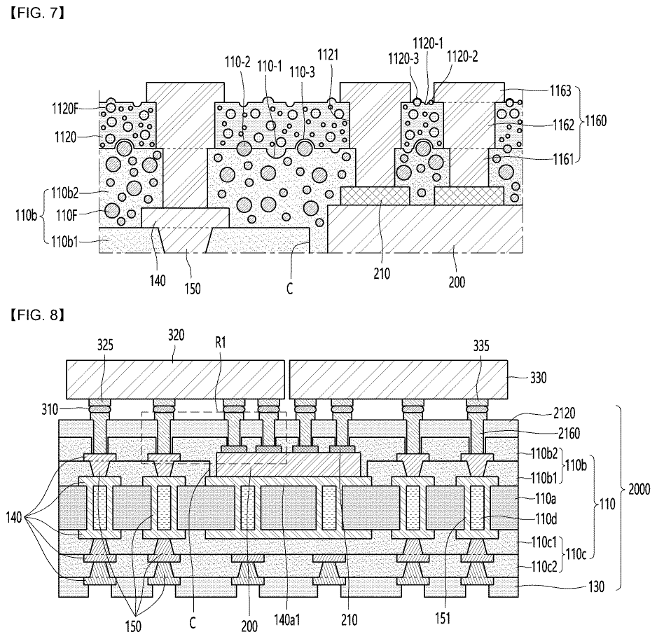

FIG. 8 is a cross-sectional view illustrating a semiconductor package according to a third embodiment, and FIG. 9 is an enlarged view of a partial region R1 of FIG. 8.

The semiconductor package according to the third embodiment may differ in a structure of the bump part and the first protective layer compared to the semiconductor package of the second embodiment illustrated in FIGS. 5 to 7. Therefore, detailed descriptions of components having substantially the same characteristics as the semiconductor package of the second embodiment will be omitted below.

Referring to FIGS. 8 and 9, the semiconductor package of the third embodiment includes an insulating layer 110 and a first protective layer 2120 disposed on the insulating layer 110. In addition, the semiconductor package includes a bump part 2160 penetrating from the upper surface of the first protective layer 1120 to a portion of the insulating layer 110. The bump part 2160 is a metal layer formed through a single plating process, similar to the second embodiment, and thus can penetrate from the upper surface of the first protective layer 2120 to a portion of the insulating layer 110.

In this case, the bump part 1160 of the second embodiment includes a first through part 1161 and a second through part 1162, and each of side surfaces of the first through part 1161 and the second through part 1162 may have a step.

In contrast, the bump part 2160 of the third embodiment can penetrate the insulating layer 110 and the first protective layer 2120 without a step on its side surface. That is, the bump part 2160 includes a through part 2161 penetrating from the upper surface of the first protective layer 2120 to a portion of the insulating layer 110.

Furthermore, the bump part 2160 includes a protruding part 2162 disposed on the through part 2161. The protruding part 2162 is disposed on the through part 2161 and protrudes above the upper surface of the first protective layer 2120.

The first protective layer 2120 includes a first portion 2120A disposed on the insulating layer 110. Furthermore, the first protective layer 2120 includes a second portion 2120B extending from the first portion 2120A in a downward direction and penetrating the insulating layer 110.

The first protective layer 2120 includes a second portion 2120B that fills at least a portion of a through hole 110b-1 provided in the insulating layer 110. The second portion 2120B of the first protective layer 2120 is disposed in the through hole 110b-1 provided in the insulating layer 110, and thus, the second portion 2120B of the first protective layer 2120 can penetrate the insulating layer 110.

That is, the second through hole 1121 provided in the first protective layer 1120 of the second embodiment is provided to overlap with the first through hole 110b-1 provided in the insulating layer 110 in a vertical direction and to have a larger width than the first through hole 110b-1. Accordingly, the first through part 1161 of the bump part 1160 of the second embodiment is provided within the first through hole 110b-1 of the insulating layer 110 and surrounded by the insulating layer 110. In addition, the second through part 1162 of the bump part 1160 of the second embodiment is provided within the second through hole 1121 of the first protective layer 1120 and surrounded by the first protective layer 1120.

In contrast, a width of the second through hole 2121 of the first protective layer 2120 of the third embodiment is smaller than a width of the first through hole 110b-1 provided in the insulating layer 110. Accordingly, a portion of the first through hole 110b-1 provided in the insulating layer 110 may be filled with the through part 2161 of the bump part 2160, and a remaining portion of the first through hole 110b-1 may be filled with the first protective layer 2120.

That is, the through part 2161 of the bump part 2160 is disposed in the first through hole 110b-1 of the insulating layer 110. At this time, the through part 2161 may not be in contact with the insulating layer 110.

In addition, the first protective layer 2120 includes a second portion 2120B provided in the first through hole 110b-1 of the insulating layer 110 to surround the side of the through hole 110b-1. Therefore, according to the third embodiment, the through part 2161 of the bump part 2160 is in contact with the first protective layer 2120 and does not contact the insulating layer 110. Accordingly, the stress applied to the insulating layer 110 can be absorbed by the first protective layer 2120 and not transmitted to the through part 2161 of the bump part 2160. Through this, the embodiment can further improve the physical reliability and/or electrical reliability of the bump part 2160. Furthermore, the embodiment can allow the entire region of the through part 2161 of the bump part 2160 to be in contact with the first protective layer 2120, thereby uniformly applying stress to the through hole 110b-1. Therefore, the embodiment can solve the problem of cracks occurring due to stress being concentrated on a specific region of the bump part 2160.

The upper and lower surfaces of the through part 2161 of the bump part 2160 may have corresponding or identical widths. This can be achieved by forming a through hole in each of the insulating layer 110 and the first protective layer 2120 using a dry film pattern. Therefore, the embodiment can refine the width and pitch of the through part 2161 of the bump part 2160 compared to the via electrode of the comparative example provided in the through hole formed through a laser process, thereby making it possible to have a horizontal distance P1 between the centers of a plurality of adjacent bump parts 2160 of 40 μm or less. That is, the width of the upper surface of the through part 2161 can satisfy a range of 90% to 110%, or a range of 95% to 105%, or a range of 96% to 104%, or a range of 97% to 103% of the width of the lower surface of the through part 2161. In addition, the slope of the side surface 2161S of the through part 2161 may range from 85 degrees to 95 degrees with respect to the upper or lower surface of the through part 2161.

The width W1 of the through part 2161 of the bump part 2160 may range from 15 μm to 20 μm.

If the width W1 of the through part 2161 is less than 15 μm, the allowable current of the signal transmitted through the through part 2161 may decrease, and thus electrical characteristics may be degraded.

If the width W1 of the through part 2161 exceeds 20 μm, it may be difficult to maintain the horizontal distance P1 between two adjacent bump parts 2160 to 40 μm or less.

The bump part 2160 includes a protruding part 2162 disposed on the through part 2161. The protruding part 2162 may have a width greater than the through part 2161, and therefore, the protruding part 2162 may be disposed to extend in the horizontal direction on the through part 2161.

A width W2 of the protruding part 2162 may satisfy a range of 25 μm to 34 μm. If the width W2 of the protruding part 2162 is less than 25 μm, an alignment between the protruding part 2162 and the through part 2161 in a vertical direction may deteriorate, thereby deteriorating the physical and/or electrical reliability of the bump part 2160. If the width W2 of the protruding part 2162 is less than 25 μm, a contact area with the bonding part 310 may not be secured, and thus it may be difficult for the semiconductor device to be stably disposed on the protruding part 2162.

If the width W2 of the protruding part 2162 exceeds 34 μm, it may be difficult to maintain the horizontal distance P1 between two adjacent bump parts 2160 to 40 μm or less. If the width W2 of the protruding part 2162 exceeds 34 μm, the spacing between the two adjacent bump parts decreases, which may result in an electrical short circuit problem in which the two adjacent bump parts are electrically connected to each other.

In addition, the spacing W3 between the protruding parts of two adjacent bump parts among the bump parts 2160 overlapping the connection member 200 in a vertical direction may satisfy a range of 5 μm to 15 μm. If the spacing W3 is less than 5 μm, an electrical short circuit problem in which multiple adjacent bump parts are electrically connected to each other may occur due to process deviation during the plating process of the bump part 2160. In addition, if the spacing W3 exceeds 15 μm, it may be difficult to maintain the horizontal distance P1 between two adjacent bump parts 2160 to 40 μm or less.

Furthermore, the upper surfaces of the insulating layer 110 and the second protective layer 2120 of the third embodiment may each have a concave surface and a convex surface, as illustrated in FIG. 7.

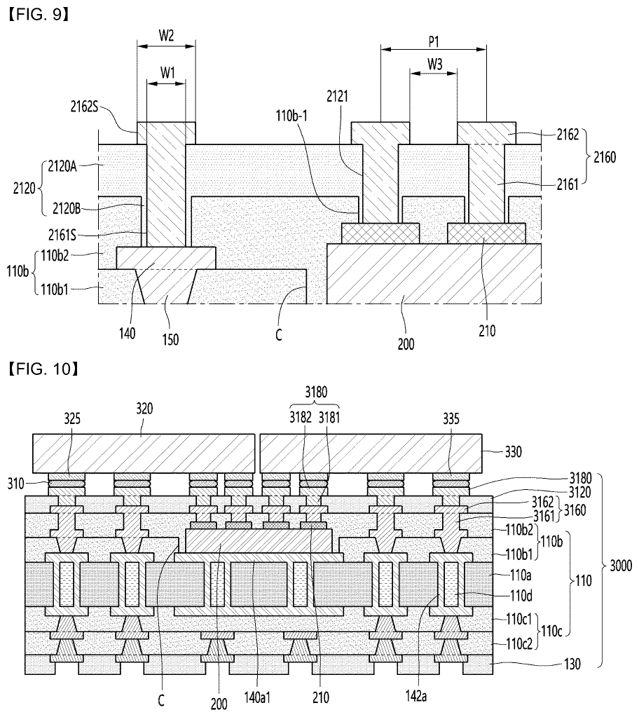

FIG. 10 is a cross-sectional view illustrating a semiconductor package according to a fourth embodiment.

Referring to FIG. 10, the semiconductor package of the fourth embodiment includes an electrode part 3160 and a bump part 3180.

The electrode part 3160 is formed through the insulating layer 110. The bump part 3180 is formed through the first protective layer 3120. At this time, through holes are formed in each of the insulating layer 110 and the first protective layer 3120. The through holes formed in the insulating layer 110 and the first protective layer 3120 are formed using the dry film pattern described in the previous embodiment. Therefore, a detailed description thereof will be omitted.

In the second and third embodiments, the bump part is formed to completely fill the through holes formed in the insulating layer and the first protective layer, respectively.

In contrast, the fourth embodiment may first form the first through hole in the insulating layer 110 and then form the electrode part 3160. Furthermore, the embodiment may laminate the first protective layer 3120 after the electrode part 3160 has been formed. In addition, the embodiment may form a through hole in the first protective layer 3120 after the first protective layer 3120 is laminated. In addition, the embodiment may perform a process of forming a bump part 3180 after the through hole is formed in the first protective layer 3120.

Therefore, the electrode part 3160 may include a via part 3161 penetrating the insulating layer 110 and a pad part 3162 disposed on the via part 3161. At this time, the via part 3161 may have structural characteristics corresponding to the via electrode 160 of the first embodiment, and thus, a detailed description thereof will be omitted. The pad part 3162 of the electrode part 3160 is disposed on the via part 3161. The pad part 3162 may have a width greater than the width of the via part 3161. The pad part 3162 may be a via land portion corresponding to an annual ring portion disposed on the via part 3161. In the fourth embodiment, the via part 3161 and the pad part 3162 of the electrode part 3160 are formed after forming a through hole in the insulating layer 110 using the first dry film pattern, thereby reducing the width and pitch of the via part 3161, thereby reducing the width and pitch of the pad part 3162.

The bump part 3180 is disposed on the electrode part 3160. The bump part 3180 includes a through part 3181 penetrating the first protective layer 3120. The through part 3181 may correspond to a portion of the second through part 1162 of the second embodiment and/or the through part 2161 of the third embodiment. Accordingly, a detailed description thereof will be omitted.

The bump part 3180 includes a protruding part 3182 disposed on the through part 3181. The protruding part 3182 may correspond to the protruding parts 1163 and 2162 described in the second and third embodiments, and thus, a detailed description thereof will be omitted.

According to the fourth embodiment, the insulating layer and the first protective layer are each provided with a through hole formed using a dry film pattern. In the second and third embodiments, the bump part is formed in a single process after the through hole is formed in the insulating layer and the first protective layer, respectively. In contrast, the fourth embodiment preferentially forms the electrode part 3160 including the via part 3161 and the pad part 3162 after the through hole is formed in the insulating layer. Afterwards, the embodiment proceeds with a process of forming a bump part 3180 by forming a through hole in the first protective layer 3120 after forming the electrode part 3160.

The embodiment includes a protective layer and a bump part penetrating from the upper surface of the protective layer to a partial region of the protective layer. At this time, the protective layer includes a through hole corresponding to the bump part. The through hole in the protective layer is formed using a dry film pattern. Accordingly, the embodiment can refine the width and pitch of the through hole provided in the protective layer. For example, the embodiment can allow a horizontal distance between centers of at least two adjacent through holes to be 40 μm or less. Accordingly, the embodiment can allow a horizontal distance between centers of adjacent bump parts to be 40 μm or less.

Therefore, the embodiment can minimize a pitch of the bump part to 40 μm or less, thereby improving circuit integration and miniaturizing the circuit board and semiconductor package. In addition, the embodiment can reduce a distance between a plurality of bump parts, thereby minimizing a transmission distance of signals transmitted through the corresponding bump parts. Therefore, the embodiment may minimize signal transmission loss that increases according to the transmission distance of the signal, thereby improving communication characteristics of a circuit board and a semiconductor package. In addition, the embodiment can allow a semiconductor device disposed on a circuit board to operate stably, thereby allowing an electronic product such as a server to which a semiconductor package is applied to operate stably.

In addition, the embodiment includes a via electrode. The via electrode is formed by penetrating an insulating layer disposed under a protective layer. At this time, the via electrode protrudes on the insulating layer. In addition, the via electrode penetrates at least a portion of the protective layer. Thus, the embodiment can eliminate via land portions (e.g., annual rings) that are formed on the via electrode and have a width greater than a width of the via electrode. Therefore, the embodiment can minimize the width and pitch of the via electrode, thereby further minimizing the width and pitch of the bump parts disposed on the via electrode.

Furthermore, the embodiment can minimize a height deviation of a plurality of bump parts. That is, the embodiment includes a first bump part overlapping a connection member in a vertical direction and a second bump part that does not overlap the connection member in a vertical direction. At this time, the first bump part and the second bump part can be manufactured in a same manner and can have a same size. Therefore, the embodiment can minimize a height deviation caused by a size difference between the first and second bump parts. Through this, the embodiment can allow a semiconductor device to be stably disposed on the first bump part and the second bump part. Therefore, the embodiment can improve operating characteristics of the first and second semiconductor devices. In addition, the embodiment can allow the first and second semiconductor devices to operate smoothly, thereby allowing the electronic product or server to operate smoothly.

In addition, the embodiment allows the first and second bump parts to have the same height, thereby resolving issues such as impedance changes and signal transmission loss caused by variations in the thickness of the first and second bump parts, as well as issues with semiconductor devices being disposed in an inclined position, thereby further improving electrical reliability.

In addition, the embodiment may allow each of the via electrode and the bump part to be disposed in a through hole provided in the insulating layer and the protective layer without contacting the filler. This is because the through holes formed in the insulating layer and protective layer are formed using a dry film rather than a laser process. Through this, the embodiment can reduce a surface roughness of the via electrode and the bump part, thereby minimizing the signal transmission loss that increases in proportion to the surface roughness. Accordingly, the embodiment can further improve the operating characteristics of the semiconductor device.

Meanwhile, an upper surface of the insulating layer and/or protective layer of the embodiment includes a convex surface and a concave surface formed by a process for thinning the thickness. The convex surface and the concave surface can increase a surface area of the insulating layer and/or the protective layer. In this case, the convex surface and the concave surface can function to mitigate the degree of expansion of the insulating layer and/or the protective layer due to heat generated during the operation of the semiconductor device. For example, since the convex surface and the concave surface have different thicknesses and/or heights, the volume deformed during thermal expansion may differ. That is, the concave surface may have a lower height than the convex surface, and due to the difference in thermal expansion rates between the convex surface and the concave surface, thermal deformation of the semiconductor package can be suppressed as a whole. Therefore, the embodiment can prevent electrical disconnection of a semiconductor device coupled to an upper portion of the semiconductor package during thermal expansion, thereby improving product reliability.

Furthermore, the embodiment can form via electrodes and/or bump parts that vertically overlap with the connection member and via electrodes and/or bump parts that do not vertically overlap with the connection member using the same method, while ensuring that the via electrodes and/or bump parts that overlap with the connection member in a vertical direction have a required width and pitch. This can improve product yield.

Furthermore, the bump parts of the embodiment penetrate from the upper surface of the protective layer to a partial region of the insulating layer. For example, the embodiment forms a through hole in each of the insulating layer and the protective layer. Thereafter, the embodiment simultaneously fills the through hole in the insulating layer and the through hole in the protective layer with a conductive material. Through this, the bump part can penetrate the insulating layer while penetrating the protective layer. Through this, the embodiment can simplify the manufacturing process and further improve product yield.

In addition, a side surface of the bump part may have a step. For example, the bump part may include a first through part penetrating the insulating layer, a second through part penetrating the protective layer, and a protruding part disposed on the second through part. In this case, side surfaces of the first through part, the second through part, and the protruding part may have a step. Through this, the embodiment can efficiently distribute the stress acting on the first through part, the second through part, and the protruding part. For example, stress acting due to thermal expansion and/or thermal contraction may not be concentrated in a specific region of the bump part due to the step, and may be evenly dispersed in an entire region of the bump part. Accordingly, the embodiment can solve the reliability problem of cracks occurring in the bump part due to stress acting due to thermal expansion and/or thermal contraction. Furthermore, the embodiment can increase a contact area between the bump part and the insulating layer and/or the protective layer by allowing the side surface of the bump part to have a step, thereby improving the bonding strength. Accordingly, the embodiment can solve the problem of the bump part being peeled off from the insulating layer and/or the protective layer, thereby allowing the semiconductor package to operate stably.

Furthermore, the protective layer of the embodiment penetrates at least a portion of the insulating layer. For example, the protective layer includes a first portion formed on the insulating layer and a second portion formed in a through hole of the insulating layer. The second portion of the protective layer surrounds a side portion of the through part of the bump part formed in the through hole of the insulating layer. Accordingly, the through part of the bump part can penetrate the protective layer and the insulating layer without contacting the insulating layer. This allows stress acting on the insulating layer to be absorbed by the protective layer and not transmitted to the bump part. Through this, the embodiment can further improve the physical reliability and/or electrical reliability of the bump part.

Hereinafter, a method for manufacturing a semiconductor package according to the first to fourth embodiments will be described in detail.

Hereinafter, the manufacturing method of the via electrode and/or bump part according to each embodiment will be described.

FIGS. 11 to 22 are cross-sectional views illustrating a method for manufacturing a semiconductor package according to a first embodiment illustrated in FIG. 1 in order of processes.

Referring to FIG. 11, the embodiment prepares a first insulating layer 110a. Furthermore, the embodiment may perform a process of forming a first electrode 140 and a second electrode 150 on the first insulating layer 110a. For example, the embodiment may perform a process of forming wiring electrodes on the upper and lower surfaces of the first insulating layer 110a, and a process of forming a via electrode and an insulating member 110d penetrating the first insulating layer 110a.

Next, the embodiment performs a process of laminating a first layer 110b1 of a second insulating layer 110b on a first insulating layer 110a. Furthermore, the embodiment performs a process of forming a second electrode 150 penetrating the first layer 110b1 of the second insulating layer 110b and a first electrode 140 on the first layer 110b1 of the second insulating layer 110b.

Referring to FIG. 12, the embodiment performs a process of forming a cavity C in the first layer 110b1 of the second insulating layer 110b. At this time, a dummy electrode 141a1 is provided on the first insulating layer 110a, and the cavity C overlaps the dummy electrode 1 41a1 in a vertical direction.

Referring to FIG. 13, the embodiment may apply an adhesive material on a dummy electrode 141a1, thereby attaching a connection member 200 to a cavity C. At this time, the connection member 200 includes a pad 210, and the pad 210 is disposed so as to face upward.

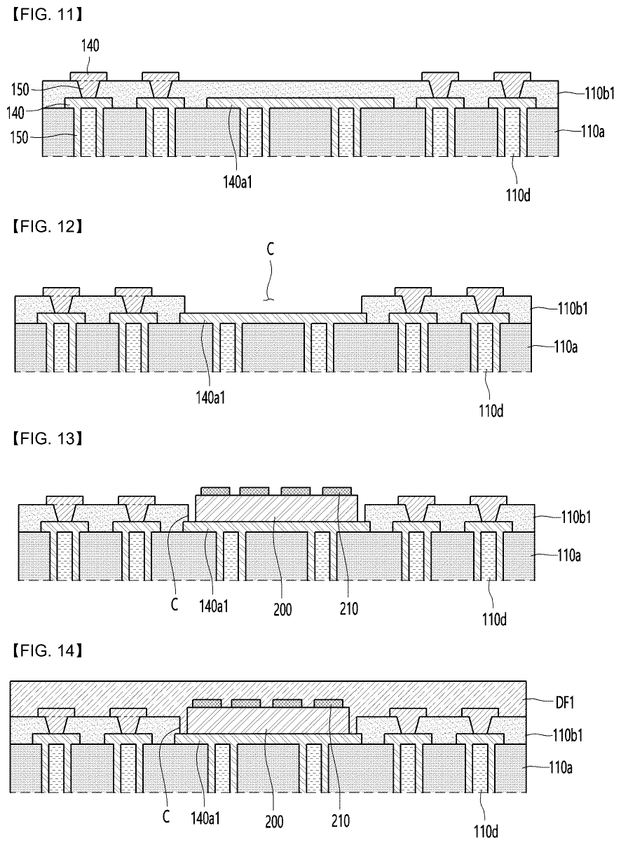

Referring to FIG. 14, the embodiment may perform a process of laminating a first dry film DF1 on the first insulating layer 110 and the connection member 200.

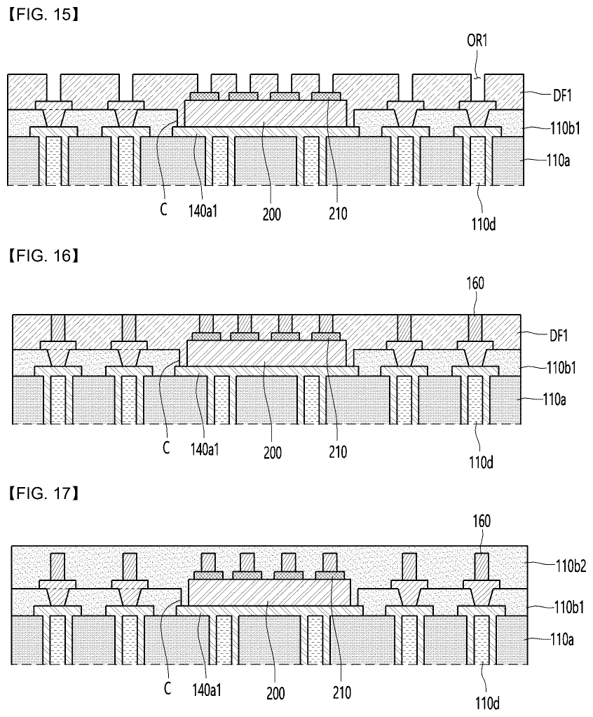

Referring to FIG. 15, the embodiment may perform a process of exposing and developing the first dry film DF1. Through this, the embodiment may perform a process of forming an opening OR1 in the first dry film DF1 that overlaps the pad 210 of the connection member 200 and the first electrode 140 in a vertical direction.

Referring to FIG. 16, the embodiment performs a process of forming a via electrode 160 by filling an opening OR1 of a first dry film DF1 with a conductive material. As a result, the side surface of the via electrode 160 has a slope corresponding to the inner wall of the opening OR1 of the first dry film DF1. For example, the side surface of the via electrode 160 may have a slope ranging from 85 degrees to 95 degrees with respect to the upper surface and/or lower surface of the via electrode 160.

Referring to FIG. 17, the embodiment performs a process of removing the first dry film DF1. Accordingly, the via electrode 160 may be disposed on the first electrode 140 and the pad 210 of the connection member 200. Thereafter, the embodiment performs a process of laminating the second layer 110b2 of the second insulating layer 110b while the via electrode 160 is disposed. At this time, the second layer 110b2 of the second insulating layer 110b is disposed to fill the cavity C in which the connection member 200 is embedded. In addition, the second layer 110b2 of the second insulating layer 110b is disposed to entirely cover the via electrode 160.

Referring to FIG. 18, the embodiment performs an etching process to thin a thickness of the second layer 110b2 of the second insulating layer 110b. That is, the embodiment performs a process of thinning the thickness of the second layer 110b2 of the second insulating layer 110b until the upper surface of the second layer 110b2 of the second insulating layer 110b is positioned lower than the upper surface of the via electrode 160. Accordingly, the via electrode 160 has a structure that protrudes above the upper surface of the second layer 110b2 of the second insulating layer 110b.

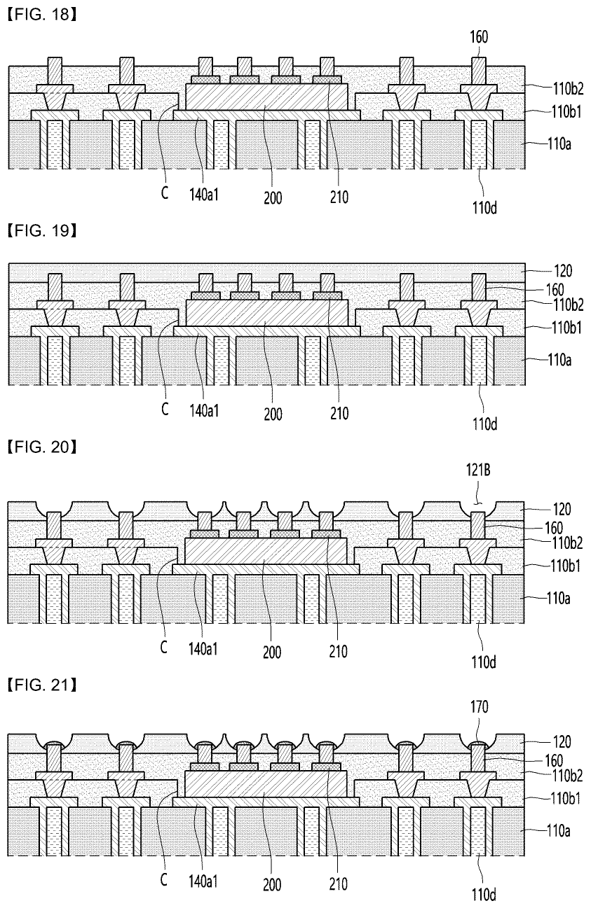

Referring to FIG. 19, the embodiment performs a process of laminating a first protective layer 120 on the second layer 110b2 of the second insulating layer 110b. At this time, the first protective layer 120 is disposed to cover at least a portion of the via electrode 160.

Referring to FIG. 20, the embodiment performs a process of removing a portion of the first protective layer 120 that vertically overlaps the via electrode 160 through etching. For example, the embodiment performs a process of forming a second part 121B of a through hole in the first protective layer 120. Accordingly, the upper surface of the second layer 110b2 of the second insulating layer 110b can have a convex surface and a concave surface through the etching process.

Referring to FIG. 21, the embodiment performs a process of forming a metal layer 170 on the via electrode 160 exposed through the second part 121B of the through hole in the first protective layer 120.

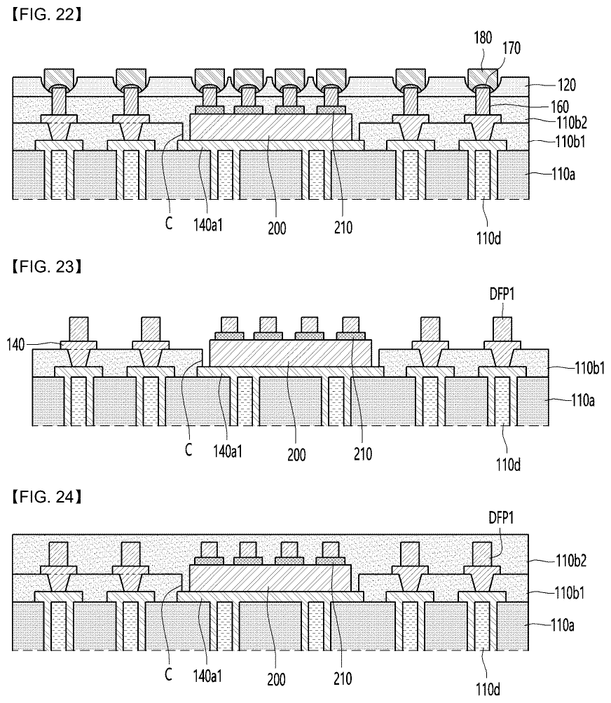

Referring to FIG. 22, the embodiment performs a process of forming a bump part 180 on the metal layer 170. To this end, the embodiment may include a process of placing a dry film having an opening that vertically overlaps the metal layer 170 on the first protective layer 120, and a process of filling the opening of the dry film with a conductive material to form a bump part 180.

FIGS. 23 to 30 are cross-sectional views illustrating a method for manufacturing a semiconductor package according to a second embodiment illustrated in FIG. 5 in order of processes. In the manufacturing method of the semiconductor package of the second embodiment, descriptions of processes identical to those of the manufacturing method of the semiconductor package of the first embodiment are omitted.

Referring to FIG. 23, the embodiment forms a first dry film pattern DFP1 on the first electrode 140 and the pad 210 of the connection member 200. To this end, the embodiment laminates the first dry film on the first electrode 140 and the pad 210 of the connection member 200. Thereafter, the embodiment forms a first dry film pattern DFP1 by exposing and developing the first dry film. For example, the embodiment forms the first dry film pattern DFP1 corresponding to a position where the first through hole 110b-1 of the second layer 110b2 of the second insulating layer 110b is to be formed. That is, the first embodiment preferentially forms the via electrode 160 using the opening of the first dry film. In contrast, the second embodiment forms the first dry film pattern DFP1 corresponding to the position where the first through hole 110b-1 is to be formed by patterning the first dry film.

Referring to FIG. 24, the embodiment performs a process of laminating the second layer 110b2 of the second insulating layer 110b. The second layer 110b2 of the second insulating layer 110b is disposed to cover the first dry film pattern DFP1.

Referring to FIG. 25, the embodiment performs a process of thinning the thickness of the second layer 110b2 of the second insulating layer 110b. Through this, a height of the upper surface of the second layer 110b2 of the second insulating layer 110b may be lower than a height of the upper surface of the first dry film pattern DFP1. Accordingly, the upper surface of the second layer 110b2 of the second insulating layer 110b may have a convex surface and a concave surface corresponding to the filler.

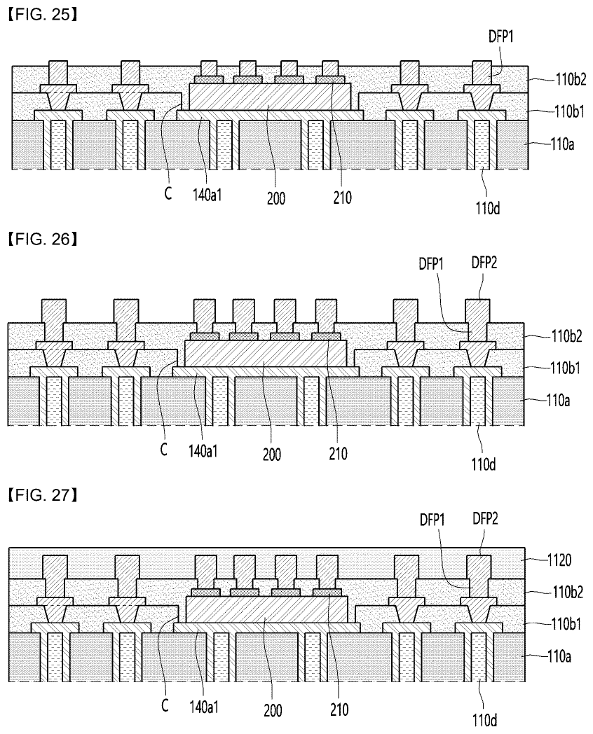

Referring to FIG. 26, the embodiment performs a process of forming a second dry film pattern DFP2 on the first dry film pattern DFP1. The second dry film pattern DFP2 has a width greater than the width of the first dry film pattern DFP1.

Referring to FIG. 27, the embodiment performs a process of laminating a first protective layer 1120 on the second layer 110b2 of the second insulating layer 110b. The first protective layer 1120 is laminated to entirely cover the second dry film pattern DFP2.

Referring to FIG. 28, the embodiment performs a process of thinning the thickness of the first protective layer 1120. Through this, the upper surface of the first protective layer 1120 can be positioned lower than the upper surface of the second dry film pattern DFP2. Furthermore, the upper surface of the first protective layer 1120 can have a convex surface and a concave surface corresponding to the filler.

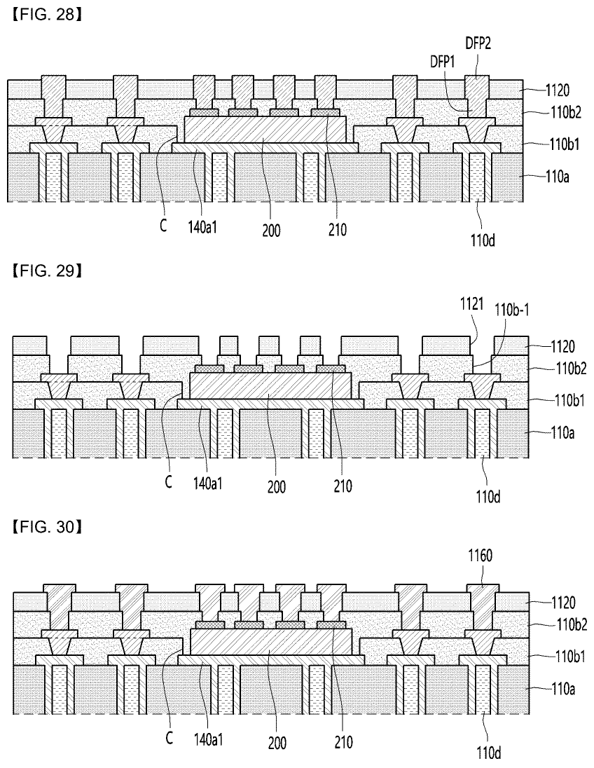

Referring to FIG. 29, the embodiment performs a process of removing the first dry film pattern DFP1 and the second dry film pattern DFP2. Accordingly, the second layer 110b2 of the second insulating layer 110b is provided with a first through hole 110b-1 corresponding to a region from which the first dry film pattern DFP1 is removed. Furthermore, the second protective layer 1120 is provided with a second through hole 1121 corresponding to a region from which the second dry film pattern DFP2 is removed.

Referring to FIG. 30, the embodiment performs a process of forming a bump part 1160. To this end, the embodiment may laminate a third dry film having an opening on the first protective layer 1120. An opening of the third dry film may have a larger width than the second through hole 1121 while overlapping the first through hole 110b-1 and the second through hole 1121 in a vertical direction. Next, the embodiment proceeds with a process of forming a bump part 1160 by filling the first through hole 110b-1, the second through hole 1121, and the opening of the third dry film with a conductive material. Thus, the bump part 1160 may include a first through part 1161 provided in the first through hole 110b-1, a second through part 1162 provided in the second through hole 1121, and a protruding part 1163 provided in the opening of the third dry film.

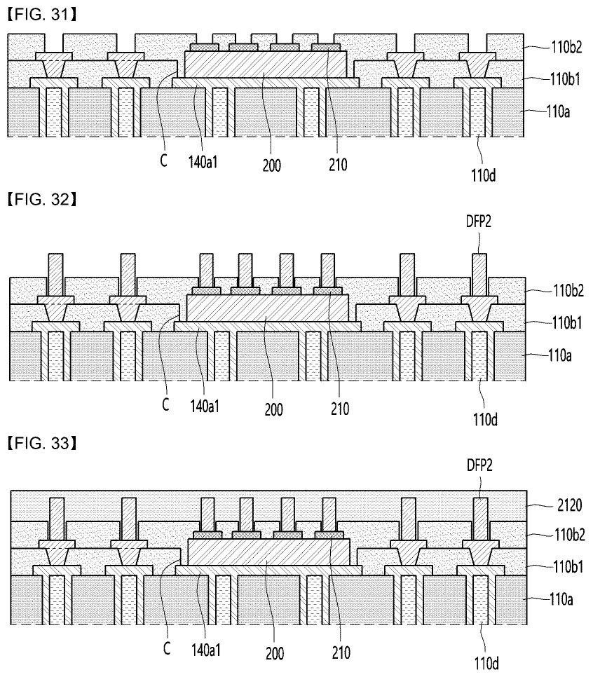

FIGS. 31 to 36 are cross-sectional views illustrating a method for manufacturing a semiconductor package according to a third embodiment illustrated in FIG. 8 in order of processes. Descriptions of processes identical to those of the first and second embodiments in the method for manufacturing the semiconductor package of the third embodiment are omitted.

Referring to FIG. 31, the embodiment performs a process of forming a first through hole 110b-1 of the second layer 110b2 of the second insulating layer 110b. For example, a process of removing the first dry film pattern DFP1 may be performed after performing the process illustrated in FIG. 25. Accordingly, the first through hole 110b-1 corresponding to the first dry film pattern DFP1 may be preferentially provided in the second layer 110b2 of the second insulating layer 110b.

Referring to FIG. 32, the embodiment may perform a process of forming a second dry film pattern DFP2. To this end, the embodiment may perform a process of laminating a second dry film and exposing and developing the second dry film. At this time, the second dry film pattern DFP2 overlaps the first through hole 110b-1 in the vertical direction. Furthermore, the second dry film pattern DFP2 has a smaller width than the first through hole 110b-1. Therefore, the second dry film pattern DFP2 is provided to protrude above the second layer 110b2 of the second insulating layer 110b while filling at least a portion of the first through hole 110b-1.

Referring to FIG. 33, the embodiment performs a process of laminating a first protective layer 2120 on the second layer 110b2 of the second insulating layer 110b. The first protective layer 2120 is laminated to entirely cover the second dry film pattern DFP2. At this time, a portion of the first through hole 110b-1 provided in the second layer 110b2 of the second insulating layer 110b before the first protective layer 2120 is laminated has a second dry film pattern DFP2 disposed therein, and a remaining portion of the first protective layer 2120 is provided as an empty space. Accordingly, the first protective layer 2120 is provided to fill the empty space of the first through hole 110b-1 of the second layer 110b2 of the second insulating layer 110b. Accordingly, the first protective layer 2120 can be provided in the first through hole 110b-1 of the second layer 110b2 of the second insulating layer 110b, and thus can penetrate the second layer 110b2 of the second insulating layer 110b.

Referring to FIG. 34, the embodiment performs an etching process to thin the first protective layer 2120. Accordingly, the upper surface of the first protective layer 2120 may be positioned lower than the upper surface of the second dry film pattern DFP2.

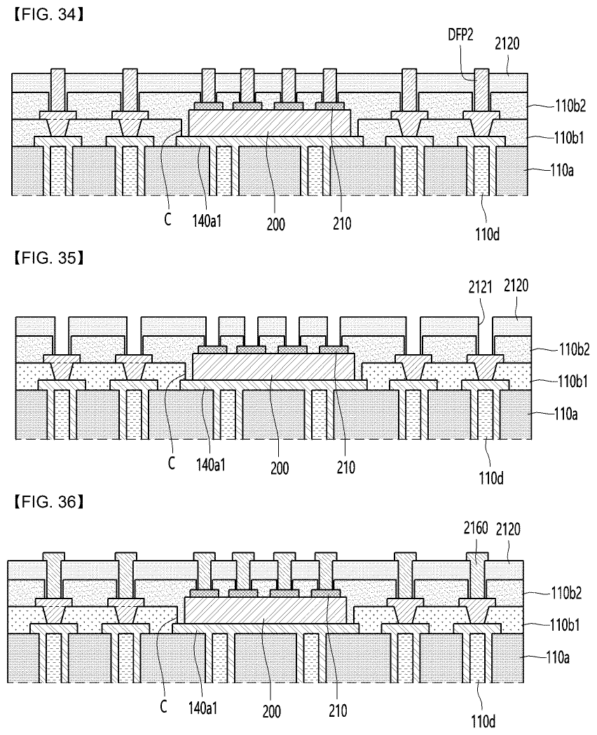

Referring to FIG. 35, the embodiment performs a process to remove the second dry film pattern DFP2. Accordingly, the first protective layer 2120 may be provided with a second through hole 2121 corresponding to a space where the second dry film pattern DFP2 was removed.

Referring to FIG. 36, the embodiment performs a process to form a bump part 2160 by filling the first through hole 110b-1 of the second layer 110b2 of the second insulating layer 110b and the second through hole 2121 of the first protective layer 2120 with a conductive material.

FIGS. 37 to 41 are cross-sectional views illustrating a method for manufacturing a semiconductor package according to a fourth embodiment illustrated in FIG. 10 in order of processes. Descriptions of processes identical to those of the semiconductor package manufacturing methods of the first to third embodiments in the method for manufacturing the semiconductor package of the fourth embodiment are omitted.

Referring to FIG. 37, the embodiment performs a process for forming a first through hole 110b-1 in the second layer 110b2 of the second insulating layer 110b. For example, the embodiment may form the first through hole 110b-1 by performing the process illustrated in FIG. 31.

Referring to FIG. 38, the embodiment performs a process for forming an electrode part 3160 including a via part 3161 and a pad part 3162 by filling the first through hole 110b-1 with a conductive material. To this end, the embodiment laminates a second dry film DF2 including an opening on the second layer 110b2 of the second insulating layer 110b. Thereafter, the embodiment may fill the first through hole 110b-1 of the second layer 110b2 of the second insulating layer 110b and the opening of the second dry film DF2 with a conductive material to form a via part 3161 and a pad part 3162 of the electrode part 3160, respectively.

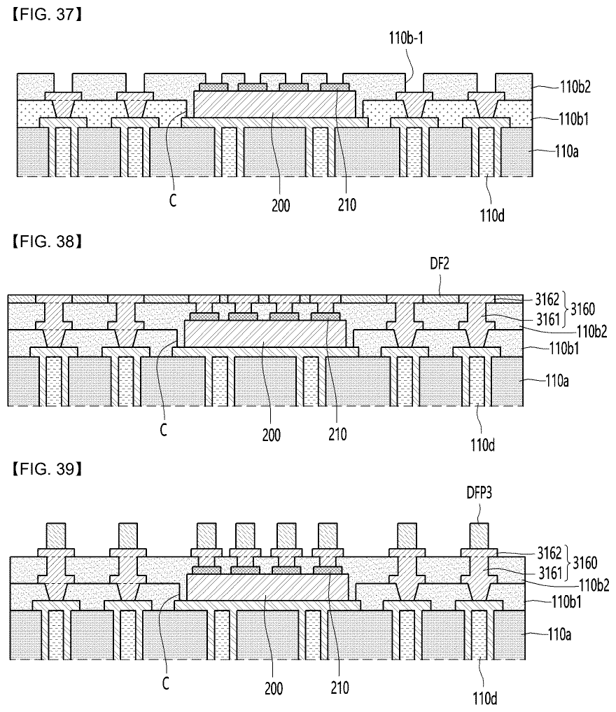

Referring to FIG. 39, the embodiment performs a process of forming a third dry film pattern DFP3 on the pad part 3162 of the electrode part 3160. For example, the embodiment forms the third dry film pattern DFP3 corresponding to a position where the through hole of the first protective layer 3120 is to be formed. At this time, the process of forming the third dry film pattern DFP3 may correspond to the process of forming a specific dry film pattern in the previous embodiment, and a detailed description thereof is omitted.

Referring to FIG. 40, the embodiment laminates a first protective layer 3120 on the second layer 110b2 of the second insulating layer 110b. At this time, the first protective layer 3120 is formed to entirely cover the third dry film pattern DFP3. Thereafter, the embodiment performs an etching process to thin the thickness of the first protective layer 3120. Thereafter, the embodiment performs a process to remove the third dry film pattern DFP3. Accordingly, the first protective layer 3120 is formed with a through hole 3121 corresponding to a removed space of the third dry film pattern DFP3.

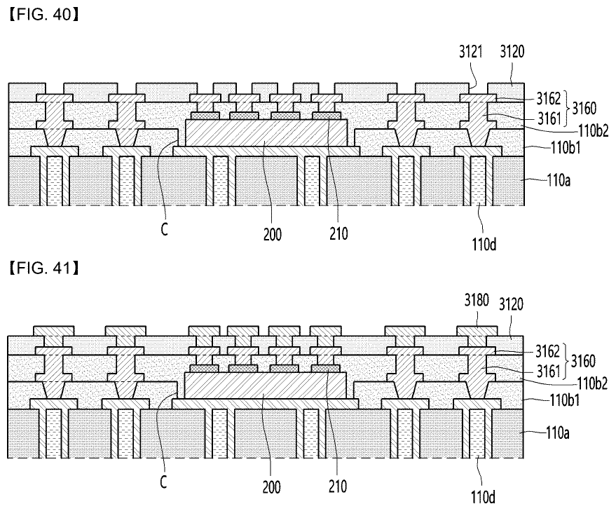

Referring to FIG. 41, the embodiment laminates a dry film having an opening that overlaps the through hole 3121 in the vertical direction on the first protective layer 3120. Thereafter, the embodiment can proceed with a process of forming a bump part 3180 by filling the opening of the dry film and the through hole 3121 of the first protective layer 3120 with a conductive material.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a build-up insulating layer including a plurality of insulating layers laminated along a vertical direction;
a protective layer disposed on the build-up insulating layer;
an electrode part embedded in the build-up insulating layer; and
a bump part disposed on the protective layer,
wherein the electrode part includes a via electrode connected to the bump part,
wherein each of the build-up insulating layer and the protective layer includes a through hole in which the via electrode is disposed, and
wherein an inner wall of the build-up insulating layer and an inner wall of the protective layer forming the through hole are positioned on a same plane.

2. The circuit board of claim 1, wherein a width of an upper surface of the via electrode satisfies a range of 90% to 110% of a width of a lower surface of the via electrode.

3. The circuit board of claim 2, wherein the width of the upper surface of the via electrode is same as the width of the lower surface of the via electrode.

4. The circuit board of claim 1, wherein the through hole of the protective layer includes a first part in contact with a side surface of the via electrode and including an inner wall having a first slope, and a second part provided on the first part and having a second slope different from the first slope.

5. The circuit board of claim 4, wherein the inner wall of the first part is same as a slope of the side surface of the via electrode.

6. The circuit board of claim 5, wherein the slope of the side surface of the via electrode satisfies a range of 85 degrees to 95 degrees with respect to the upper surface of the via electrode.

7. The circuit board of claim 4, wherein an inner wall of the second part includes a curved surface, and
wherein a lower surface of the bump part includes a portion in contact with the curved surface.

8. The circuit board of claim 1, further comprising.
a metal layer disposed between the bump part and the via electrode,
wherein the metal layer includes a different metal material from at least one of the bump part and the via electrode.

9. The circuit board of claim 4, wherein the bump part is provided in the second part of the through hole of the protective layer, and
wherein a width of the bump part is less than or equal to a width of the second part.

10. The circuit board of claim 1, wherein the build-up insulating layer includes a first filler, and
wherein an interface between an upper surface of the build-up insulating layer and a lower surface of the protective layer includes at least one of a convex surface and a concave surface corresponding to a curvature of the first filler.

11. The circuit board of claim 10, wherein the protective layer includes a second filler, and
wherein the via electrode overlaps the first and second fillers in a horizontal direction and does not contact the first and second fillers.

12. The circuit board of claim 1, further comprising:
a connection member embedded in the build-up insulating layer,
wherein the bump part includes a plurality of bumps overlapping the connection member in the vertical direction, and
wherein a horizontal distance between centers of two adjacent bumps among the plurality of bumps is 40 μm or less.

13. A circuit board comprising:
a build-up insulating layer;
a protective layer disposed on the build-up insulating layer, and
a bump part penetrating from an upper surface of the protective layer to a partial region of the build-up insulating layer,
wherein the bump part includes a through part penetrating from the upper surface of the protective layer to the partial region of the build-up insulating layer, and a protruding part disposed on the through part and protruding on the protective layer.

14. The circuit board of claim 13, wherein the through part includes a first through part penetrating the build-up insulating layer; and a second through part penetrating the protective layer,
wherein a side surface of the first through part does not have a step,
wherein a side surface of the second through part does not have a step, and
wherein a width of the second through part is greater than a width of the first through part.

15. The circuit board of claim 13, wherein a slope of the side surface of the first through part is the same as a slope of the side surface of the second through part.

16. The circuit board of claim 13, wherein the protective layer includes a first portion disposed on the build-up insulating layer, and a second portion extending from the first portion and penetrating the build-up insulating layer, and wherein the second portion surrounds a side portion of the through part of the bump part.

17. The circuit board of claim 16, wherein a width of an upper surface of the through part satisfies a range of 90% to 110% of a width of a lower surface of the through part, and
wherein a side surface of the through part does not have a step.

18. The circuit board of claim 13, wherein the build-up insulating layer includes a first filler, and
wherein an interface between an upper surface of the build-up insulating layer and a lower surface of the protective layer includes a first convex surface and a first concave surface corresponding to a curvature of the first filler.

19. The circuit board of claim 13, wherein the protective layer includes a second filler, and
wherein an upper surface of the protective layer includes a second convex surface and a second concave surface corresponding to a curvature of the second filler.

20. The circuit board of claim 13, further comprising:
a connection member embedded in the build-up insulating layer,
wherein the bump part includes a plurality of bumps overlapping the connection member in the vertical direction, and
wherein a horizontal distance between centers of two adjacent bumps among the plurality of bumps is 40 μm or less.
